(19) United States
(12) Patent Application Publication
(10) Pub. No.: US 2026/0312364 A1
(43) Pub. Date: Oct. 8, 2026

(54) LIGHT EMITTING DEVICE AND METHOD FOR MANUFACTURING THE SAME

(71) Applicant: Sony Group Corporation, Tokyo (JP)

(72) Inventors: Shuhei YAMAGUCHI, Kanagawa (JP); Hideki WATANABE, Kanagawa (JP); Yasutaka HIGA, Tokyo (JP); Gyongsok SONG, Kanagawa (JP); Tatsuya MATOU, Kanagawa (JP); Koshiro WADA, Kanagawa (JP); Rintaro KODA, Tokyo (JP)

(21) Appl. No.: 19/481,330

(22) PCT Filed: May 16, 2024
(86) PCT No.: PCT/JP2024/018130

§ 371 Date: Nov. 4, 2025

(30) Foreign Application Priority Data
Jun. 19, 2023 (JP) 2023-100349

(51) Int. Cl. H01S 5/042; H01S 5/183

(52) U.S. Cl. CPC H01S 5/04257; H01S 5/04254; H01S 5/18369

(57) ABSTRACT

Provided are a light emitting device capable of achieving suitable bonding of a substrate for a light emitting element, and a method for manufacturing the light emitting device.

A light emitting device of the present disclosure includes an active layer; a first reflector provided on a first-direction surface side of the active layer; a second reflector provided on a second-direction surface side of the active layer; a first semiconductor layer provided on the first-direction surface side of the active layer and having a first conductivity type; a second semiconductor layer provided on the second-direction surface side of the active layer and having a second conductivity type; a first electrode electrically connected to the first semiconductor layer; and a second electrode electrically connected to the second semiconductor layer, in which the first electrode and the second electrode are electrically separated from each other by a first insulating film provided between the first electrode and the second electrode, and the first-direction surface of the first electrode, the first-direction surface of the second electrode, and the first-direction surface of the first insulating film are located in a same plane.

### TECHNICAL FIELD

The present disclosure relates to a light emitting device and a method for manufacturing the same.

### BACKGROUND ART

As a type of semiconductor laser, a surface-emitting laser such as a vertical cavity surface emitting laser (VCSEL) is known. In general, in a light emitting device utilizing a surface emitting laser, a plurality of light emitting elements is formed in a two-dimensional array on a front surface or a back surface of a substrate.

### Citation List

### Patent Document

Patent Document 1: Japanese Patent No. 5434131
Patent Document 2: Japanese Patent Application Laid-Open No. 4224981

### SUMMARY OF THE INVENTION

### Problems to Be Solved by the Invention

In a case where a plurality of light emitting elements is formed on a substrate, it is desirable to narrow a pitch between the light emitting elements. However, there is a possibility that it becomes difficult to independently drive these light emitting elements. This is because it becomes more difficult to dispose a drive circuit and wiring of the light emitting element as the pitch becomes narrower. In order to achieve both the narrow pitch and the independent driving, it is conceivable to use one or both of an anode electrode and a cathode electrode of the light emitting element as a through electrode.

Whereas, the light emitting device is manufactured, for example, by bonding a substrate for the light emitting element and a substrate for the drive circuit or the wiring. In this case, in a case of adopting the through electrode described above, it is preferable to bond the substrates with use of wafer bonding rather than to bond the substrates with use of bump bonding. However, there is a possibility that wafer bonding becomes difficult depending on a shape of the light emitting element and other components.

Therefore, the present disclosure provides a light emitting device capable of achieving suitable bonding of a substrate for a light emitting element, and a method for manufacturing the light emitting device.

### Solutions to Problems

A light emitting device according to a first aspect of the present disclosure includes: an active layer having a first surface on a first substrate side and a second surface on a side opposite to the first substrate; a first reflector provided on the first surface side of the active layer; a second reflector provided on the second surface side of the active layer; a first semiconductor layer provided on the first surface side of the active layer and having a first conductivity type; a second semiconductor layer provided on the second surface side of the active layer and having a second conductivity type; a first electrode electrically connected to the first semiconductor layer; and a second electrode electrically connected to the second semiconductor layer, in which the first electrode and the second electrode are separated from each other by a first insulating film provided between the first electrode and the second electrode, and a surface of the first electrode on a side opposite to the first substrate, a surface of the second electrode on a side opposite to the first substrate, and a surface of the first insulating film on a side opposite to the first substrate are located in a same plane. As a result, for example, by performing wafer bonding on the above-described plane, it is possible to achieve suitable bonding of a substrate (first substrate) for the light emitting element.

Furthermore, in the first aspect, the second electrode may be in contact with the second reflector while avoiding a light emitting surface. As a result, for example, light from the light emitting element can pass through the second reflector.

Furthermore, in the first aspect, the first electrode may have a shape surrounding the second electrode in plan view. As a result, for example, the first electrode can be disposed around a light emitting element of a mesa type.

Furthermore, in the first aspect, the first insulating film may include the second reflector that is an insulating film. As a result, for example, by forming the first electrode and the second electrode in the second reflector, the first electrode and the second electrode can be separated from each other by the insulating film.

Furthermore, in the first aspect, the first electrode may be provided inside or on side surfaces of the active layer, the second reflector, and the second semiconductor layer, and the second electrode may be provided inside or on a side surface of the second reflector or on a surface of the second reflector on a side opposite to the substrate. As a result, for example, the first electrode and the second electrode can be used as through electrodes.

Furthermore, in the first aspect, the first electrode may be provided inside or on side surfaces of the active layer, the second reflector, and the second semiconductor layer with a second insulating film interposed in between, and the first insulating film may include the second insulating film. As a result, for example, the first electrode and the second electrode can be separated from each other by the second insulating film that is formed for the first electrode.

Furthermore, in the first aspect, the second electrode may be provided inside the second reflector that is a semiconductor layer, with a third insulating film interposed in between, and the first insulating film may include the third insulating film. As a result, for example, the first electrode and the second electrode can be separated from each other by the third insulating film that is formed for the second electrode.

Furthermore, in the first aspect, a ratio of the surface of the first insulating film to the plane may be larger than a ratio of the surface of the first electrode and the surface of the second electrode to the plane. As a result, for example, in a case where the light emitting element is not a mesa type, it is possible to achieve suitable bonding of a substrate for the light emitting element.

Furthermore, in the first aspect, a ratio of the surface of the first electrode to the plane may be larger than a ratio of the surface of the second electrode and the surface of the first insulating film to the plane. As a result, for example, in a case where the light emitting element is a mesa type, it is possible to achieve suitable bonding of a substrate for the light emitting element.

Furthermore, the light emitting device of the first aspect may further include a current constriction region having a ring shape in plan view and provided in the active layer, the first reflector, the second reflector, the first semiconductor layer, or the second semiconductor layer. As a result, for example, it is possible to form a step structure in a ring of the current constriction region, and to form an optical aperture (OA) portion that confines light by providing a refractive index difference between a step portion that is a high refractive index region and a periphery of the step portion that is a low refractive index region.

Furthermore, in the first aspect, the current constriction region may include: a first current constriction region provided in the active layer and having a first inner diameter in plan view; and a second current constriction region provided in the active layer and the second semiconductor layer and having a second inner diameter larger than the first inner diameter in plan view. As a result, for example, the current constriction can be achieved by the first current constriction region, and the light emitting elements can be separated from each other by the second current constriction region.

Furthermore, in the first aspect, the current constriction region may be in contact with the second reflector and the second electrode. As a result, for example, a light emitting element that is not a mesa type can be formed. For example, the second current constriction region described above may be in contact with the second reflector and the second electrode.

Furthermore, in the first aspect, the current constriction region may be an oxide film. As a result, for example, the current constriction region and the light confinement region can be simultaneously formed.

Furthermore, in the first aspect, the first semiconductor layer may be provided between the active layer and the first reflector or in the first reflector. As a result, for example, an intra-cavity structure can be achieved. Furthermore, the second semiconductor layer may be provided between the active layer and the second reflector. Whereas, the second reflector may be provided between the active layer and the second semiconductor layer.

Furthermore, in the first aspect, the active layer, the first reflector, the second reflector, the first semiconductor layer, and the second semiconductor layer may form a plurality of light emitting elements. As a result, for example, it is possible to achieve suitable bonding of the substrate on which the light emitting element array is provided.

Furthermore, in the first aspect, the second electrode of each light emitting element may be separated from the second electrode of another light emitting element. As a result, for example, the second electrode can be provided for every light emitting element.

Furthermore, in the first aspect, the second electrode of each light emitting element may be separated from the second electrode of another light emitting element by the first insulating film. As a result, for example, the second electrode can be provided for every light emitting element.

Furthermore, the light emitting device of the first aspect may further include: a light emitting element substrate including the first substrate, and including the active layer, the first reflector, the second reflector, the first semiconductor layer, and the second semiconductor layer that are provided on the first substrate; and a wiring substrate bonded to the light emitting element substrate and including a second substrate and wiring provided on the second substrate for the plurality of light emitting elements. As a result, for example, by bonding the light emitting element substrate (first substrate) and the wiring substrate (second substrate) on the above-described plane, it is possible to achieve suitable bonding.

A method for manufacturing a light emitting device according to a second aspect of the present disclosure includes: forming, on a first substrate, an active layer having a first surface on a first substrate side and a second surface on a side opposite to the first substrate, a first reflector provided on the first surface side of the active layer, a second reflector provided on the second surface side of the active layer, a first semiconductor layer provided on the first surface side of the active layer and having a first conductivity type, and a second semiconductor layer provided on the second surface side of the active layer and having a second conductivity type; forming, on the first substrate, a first electrode electrically connected to the first semiconductor layer; and forming, on the first substrate, a second electrode electrically connected to the second semiconductor layer, in which the first electrode and the second electrode are formed to be separated from each other by a first insulating film provided between the first electrode and the second electrode, and a surface of the first electrode on a side opposite to the first substrate, a surface of the second electrode on a side opposite to the first substrate, and a surface of the first insulating film on a side opposite to the first substrate are formed to be located in a same plane. As a result, for example, by performing wafer bonding on the above-described plane, it is possible to achieve suitable bonding of a substrate (first substrate) for the light emitting element.

Furthermore, in the second aspect, the surface of the first electrode, the surface of the second electrode, and the surface of the first insulating film are formed to be located in a same plane by being planarized by polishing. As a result, for example, by planarizing these surfaces by polishing, the above-described plane and suitable bonding can be achieved.

### BRIEF DESCRIPTION OF DRAWINGS

FIG. 1 is a cross-sectional view and a plan view illustrating a structure of a light emitting device of a first embodiment.

FIG. 2 is a cross-sectional view and a plan view (1/6) illustrating a method for manufacturing the light emitting device of the first embodiment.

FIG. 3 is a cross-sectional view and a plan view (2/6) illustrating the method for manufacturing the light emitting device of the first embodiment.

FIG. 4 is a cross-sectional view and a plan view (3/6) illustrating the method for manufacturing the light emitting device of the first embodiment.

FIG. 5 is a cross-sectional view and a plan view (4/6) illustrating the method for manufacturing the light emitting device of the first embodiment.

FIG. 6 is a cross-sectional view and a plan view (5/6) illustrating the method for manufacturing the light emitting device of the first embodiment.

FIG. 7 is a cross-sectional view and a plan view (6/6) illustrating the method for manufacturing the light emitting device of the first embodiment.

FIG. 8 is a cross-sectional view and a plan view illustrating a structure of a light emitting device of a second embodiment.

FIG. 9 is a cross-sectional view and a plan view (1/6) illustrating a method for manufacturing the light emitting device of the second embodiment.

FIG. 10 is a cross-sectional view and a plan view (2/6) illustrating the method for manufacturing the light emitting device of the second embodiment.

FIG. 11 is a cross-sectional view and a plan view (3/6) illustrating the method for manufacturing the light emitting device of the second embodiment.

FIG. 12 is a cross-sectional view and a plan view (4/6) illustrating the method for manufacturing the light emitting device of the second embodiment.

FIG. 13 is a cross-sectional view and a plan view (5/6) illustrating the method for manufacturing the light emitting device of the second embodiment.

FIG. 14 is a cross-sectional view and a plan view (6/6) illustrating the method for manufacturing the light emitting device of the second embodiment.

FIG. 15 is a cross-sectional view and a plan view illustrating a structure of a light emitting device of a third embodiment.

FIG. 16 is a cross-sectional view and a plan view illustrating a structure of a light emitting device of a fourth embodiment.

FIG. 17 is a cross-sectional view and a plan view (1/6) illustrating a method for manufacturing the light emitting device of the fourth embodiment.

FIG. 18 is a cross-sectional view and a plan view (2/6) illustrating the method for manufacturing the light emitting device of the fourth embodiment.

FIG. 19 is a cross-sectional view and a plan view (3/6) illustrating the method for manufacturing the light emitting device of the fourth embodiment.

FIG. 20 is a cross-sectional view and a plan view (4/6) illustrating the method for manufacturing the light emitting device of the fourth embodiment.

FIG. 21 is a cross-sectional view and a plan view (5/6) illustrating the method for manufacturing the light emitting device of the fourth embodiment.

FIG. 22 is a cross-sectional view and a plan view (6/6) illustrating the method for manufacturing the light emitting device of the fourth embodiment.

FIG. 23 is a cross-sectional view illustrating a structure of a light emitting device of a fifth embodiment.

FIG. 24 is a cross-sectional view illustrating a Structure of a light emitting device of a sixth embodiment.

FIG. 25 is a cross-sectional view illustrating a structure of a light emitting device of a seventh embodiment.

FIG. 26 is a cross-sectional view illustrating a Structure of a light emitting device of an eighth embodiment.

FIG. 27 is a cross-sectional view illustrating a structure of a light emitting device of a ninth embodiment.

FIG. 28 is a cross-sectional view and a plan view illustrating a structure of a light emitting device of a tenth embodiment.

FIG. 29 is a cross-sectional view and a plan view illustrating a structure of a light emitting device of an eleventh embodiment.

FIG. 30 is a cross-sectional view illustrating a Structure of a light emitting device of a twelfth embodiment.

FIG. 31 is a block diagram illustrating a configuration example of a distance measuring device 101 of a thirteenth embodiment.

FIG. 32 is a diagram for explaining a structured light (STL) method of the thirteenth embodiment.

### MODE FOR CARRYING OUT THE INVENTION

Hereinafter, embodiments of the present disclosure will be described with reference to the drawings.

### First Embodiment

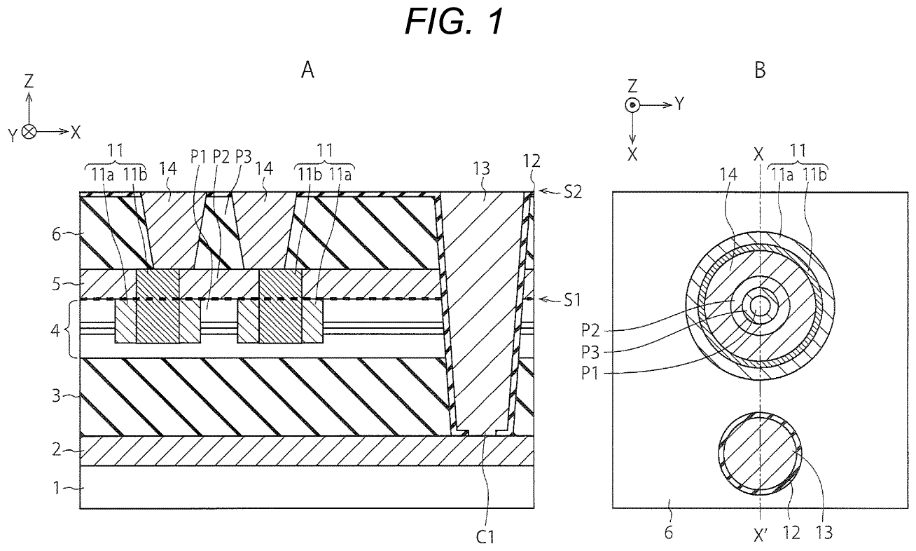

FIG. 1 is a cross-sectional view and a plan view illustrating a structure of a light emitting device of a first embodiment. The light emitting device of the present embodiment is a VCSEL light emitting device of a back-side emission type.

As illustrated in FIGS. 1A and 1B, the light emitting device of the present embodiment includes a substrate 1, a first current injection layer 2, a first distributed Bragg reflector (DBR) 3, an active layer 4, a second current injection layer 5, a second DBR 6, an implantation region 11, an insulating film 12, a first electrode 13, and a second electrode 14. The substrate 1, the first current injection layer 2, the first DBR 3, the second current injection layer 5, the second DBR 6, and the implantation region 11 are examples of a first substrate, a first semiconductor layer, a first reflector, a second semiconductor layer, a second reflector, and a current constriction region of the present disclosure, respectively. The second DBR 6 and the insulating film 12 are examples of a first insulating film of the present disclosure. The insulating film 12 is an example of a second insulating film of the present disclosure.

Furthermore, the implantation region 11 includes a first implantation region 11a and a second implantation region 11b. The first implantation region 11a is an example of a first current constriction region of the present disclosure. The second implantation region 11b is an example of a second current constriction region of the present disclosure.

FIGS. 1A and 1B illustrate an X-axis, a Y-axis, and a Z-axis perpendicular to each other. An X direction and a Y direction correspond to a lateral direction (horizontal direction), and a Z direction corresponds to a longitudinal direction (vertical direction). Furthermore, the +Z direction corresponds to an upward direction, and the −Z direction corresponds to a downward direction. Note that the −Z direction may strictly match a gravity direction, or does not necessarily strictly match the gravity direction.

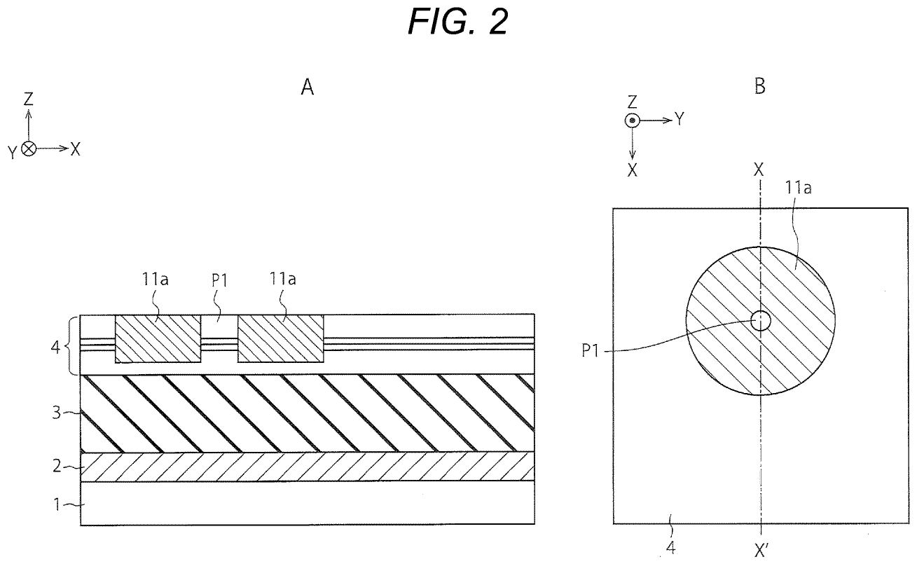

FIG. 1A is a cross-sectional view illustrating an XZ cross section of the light emitting device of the present embodiment. FIG. 1A illustrates the XZ cross section taken along line X-X′ illustrated in FIG. 1B. FIG. 1B is a plan view illustrating the light emitting device of the present embodiment as viewed from above. However, in order to describe a positional relationship between the implantation region 11, the insulating film 12, the first electrode 13, and the second electrode 14, FIG. 1B illustrates a structure of the light emitting device at a height of an XY cross section passing through the second DBR 6, the insulating film 12, the first electrode 13, and the second electrode 14, and also illustrates a position of the implantation region 11 covered by the second DBR 6. This similarly applies to FIGS. 2 to 7 described later.

### Substrate 1

The substrate 1 is, for example, a semiconductor substrate. Here, the substrate 1 is a compound semiconductor substrate such as a gallium arsenide (GaAs) substrate. In FIGS. 1A and 1B, the X direction and the Y direction are parallel to an upper surface and a lower surface of the substrate 1, and the Z direction is perpendicular to the upper surface and the lower surface of the substrate 1.

### First Current Injection Layer 2

The first current injection layer 2 is formed on the substrate 1, and is a current injection layer disposed on a lower surface side of the active layer 4.

The first current injection layer 2 is, for example, a P-type semiconductor layer.

### First DBR 3

The first DBR 3 is formed on the first current injection layer 2, and is a DBR disposed on the lower surface side of the active layer 4. The first DBR 3 includes, for example, a plurality of low refractive index layers and a plurality of high refractive index layers alternately stacked on the first current injection layer 2. The first DBR 3 is, for example, an insulating film or a semiconductor layer. For example, in a case where the substrate 1 is a GaAs substrate, the first DBR 3 is generally a semiconductor layer using an aluminum gallium arsenide (AlGaAs)-based material.

### Active Layer 4

The active layer 4 is formed on the first DBR 3. The active layer 4 has a quantum well structure, and specifically includes a plurality of quantum well layers and a plurality of barrier layers alternately stacked so as to have compressive strain. The lower surface of the active layer 4 is located on the substrate 1 side, and an upper surface of the active layer 4 is located on a side opposite to the substrate 1. The lower surface of the active layer 4 is an example of a first surface of the present disclosure. The upper surface of the active layer 4 is an example of a second surface of the present disclosure. In FIG. 1, three lines illustrated in the active layer 4 indicate quantum wells.

### Second Current Injection Layer 5

The second current injection layer 5 is formed on the active layer 4, and is a current injection layer disposed on the upper surface side of the active layer 4. The second current injection layer 5 is, for example, an N-type semiconductor layer.

### Second DBR 6

The second DBR 6 is formed on the second current injection layer 5, and is a DBR disposed on the upper surface side of the active layer 4. The second DBR 6 includes, for example, a plurality of low refractive index layers and a plurality of high refractive index layers alternately stacked on the second current injection layer 5. The second DBR 6 is, for example, an insulating film. Furthermore, the second DBR 6 may include an insulating film portion and a semiconductor layer portion.

The low refractive index layer and the high refractive index layer in the second DBR 6 are, for example, a silicon oxide (SiO₂) layer and a silicon nitride (SiN) layer. Furthermore, the low refractive index layer and the high refractive index layer in the second DBR 6 may be an SiO₂ layer and a silicon (Si) layer. Furthermore, the second DBR 6 may include a DBR including an SiO₂ portion and an SiN portion and a DBR including an SiO₂ portion and a Si portion. Such a structure is referred to as a hybrid structure. This similarly applies to the first DBR 3.

As described above, the light emitting device of the present embodiment has a stacked structure including the first current injection layer 2, the first DBR 3, the active layer 4, the second current injection layer 5, and the second DBR 6 in this order on the substrate 1. This stacked structure further includes a contact layer (not illustrated) for the first electrode 13 and a contact layer (not illustrated) for the second electrode 14. The light emitting device of the present embodiment further includes, on the lower surface of the substrate 1, a thin film having no absorption of an oscillation wavelength as an anti-reflection (AR) coating film.

### Implantation Region 11

The implantation region 11 is a high resistance region formed in the active layer 4 and the second current injection layer 5, by ion implantation. An element used for the ion implantation is only required to be an element capable of increasing resistance, and is, for example, boron (B), hydrogen (H), or oxygen (O). As illustrated in FIG. 1B, the implantation region 11 has a ring shape in plan view. FIG. 1A illustrates two portions in one implantation region 11. In the active layer 4 and the second current injection layer 5, a region surrounded by the implantation region 11 functions as a VCSEL type light emitting element. The light emitting element of the present embodiment has a structure that is not a mesa type as described above. A ring shape of the implantation region 11 is circular shape in the present embodiment, but may be other shapes (for example, an elliptical shape or a polygonal shape).

The implantation region 11 includes the first implantation region 11a having a first inner diameter in plan view and the second implantation region 11b having a second inner diameter in plan view. FIGS. 1A and 1B illustrate a region P1 surrounded in a ring shape by the first implantation region 11a and a region P2 surrounded in a ring shape by the second implantation region 11b. In the present embodiment, the second inner diameter is set to be larger than the first inner diameter. The implantation region 11 is formed by forming the first implantation region 11a by ion implantation and then forming the second implantation region 11b at a position Overlapping with the first implantation region 11a by ion implantation.

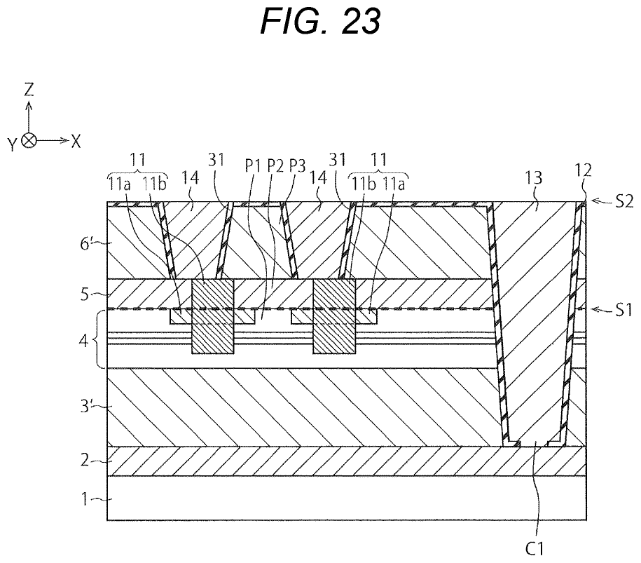

The first implantation region 11a is formed in the active layer 4, and surrounds the region P1 in a ring shape in plan view. In FIG. 1A, an upper surface of the first implantation region 11a is in contact with a lower surface of the second current injection layer 5. In FIG. 1A, further, the first implantation region 11a penetrates the quantum well in the active layer 4. The region P1 is also referred to as an optical aperture (OA) portion. As described later, in the present embodiment, for example, a step is formed in the OA portion, and a region having a higher refractive index than a periphery is formed to confine light. According to the present embodiment, it is possible to constrict a current in the OA portion by forming the first implantation region 11a in the active layer 4. Note that, as illustrated in FIG. 23 and the like to be described later, the first implantation region 11a does not need to penetrate the quantum well in the active layer 4. Furthermore, as long as the first implantation region 11a penetrates the quantum well, the second implantation region 11b does not need to penetrate the quantum well.

The second implantation region 11b is formed in the active layer 4 and the second current injection layer 5, and surrounds the region P2 in a ring shape in plan view. In FIG. 1A, an upper surface of the second implantation region 11b is in contact with a lower surface of the second DBR 6 and a lower surface of the second electrode 14. In FIG. 1A, further, the second implantation region 11b penetrates the quantum well in the active layer 4. According to the present embodiment, by forming the second implantation region 11b in the active layer 4 and the second current injection layer 5, the light emitting elements can be separated from each other by the second implantation region 11b. Note that, although the OA portion of the present embodiment is formed in the region P1 with use of the step between the region P1 and the region P2, the OA portion may be formed without using such a step in a case where a constriction layer is formed by an oxide film as described later.

### Insulating Film 12

The insulating film 12 is formed inside the first DBR 3, the active layer 4, the second current injection layer 5, and the second DBR 6, and on the second DBR 6. Specifically, the insulating film 12 is formed on side surfaces of the first DBR 3, the active layer 4, the second current injection layer 5, and the second DBR 6, an upper surface of the first current injection layer 2, and an upper surface of the second DBR 6, and has an opening C1 on the upper surface of the first current injection layer 2. The insulating film 12 is, for example, an SiO₂ layer or an SiN layer. A thickness of the insulating film 12 is, for example, 10 to 500 nm.

First electrode 13, Second electrode 14

The first electrode 13 is formed in the first DBR 3, the active layer 4, the second current injection layer 5, and the second DBR 6 with the insulating film 12 interposed in between. The first electrode 13 is buried inside the first DBR 3, the active layer 4, the second current injection layer 5, and the second DBR 6 together with the insulating film 12, and serving as a through electrode penetrating the first DBR 3, the active layer 4, the second current injection layer 5, and the second DBR 6. The first electrode 13 is in contact with the first current injection layer 2 via the opening C1, and is electrically connected to the first current injection layer 2. The first electrode 13 injects carriers into the active layer 4 via the first current injection layer 2.

The second electrode 14 is formed in the second DBR 6. The second electrode 14 is buried inside the second DBR 6, and serves as a through electrode penetrating the second DBR 6. The second electrode 14 is in contact with the second current injection layer 5, and is electrically connected to the second current injection layer 5. The second electrode 14 injects carriers into the active layer 4 via the second current injection layer 5. The second electrode 14 is further in contact with a side wall of the second DBR 6.

One of the first electrode 13 and the second electrode 14 functions as an anode electrode of the light emitting element, and another one of the first electrode and the second electrode 14 functions as a cathode electrode of the light emitting element. Here, the first electrode 13 is an anode electrode, and the second electrode 14 is a cathode electrode.

As illustrated in FIG. 1B, the first electrode 13 has a non-ring shape in plan view. As illustrated in FIG. 1B, the second electrode 14 has a ring shape in plan view. FIG. 1A illustrates two portions of one second electrode 14. Furthermore, FIGS. 1A and 1B illustrate a region P3 surrounded in a ring shape by the second electrode 14. The lower surface of the second electrode 14 includes a region in contact with an upper surface of the second current injection layer 5 and a region in contact with an upper surface of the implantation region 11. As a result, current injection and chip separation can be achieved. The lower surface of the second electrode 14 of the present embodiment is disposed at a position not overlapping with the OA portion (region P1) in the Z direction. As a result, it is possible to suppress light from the light emitting element from entering the lower surface of the second electrode 14 and being absorbed by the second electrode 14. Note that the second electrode 14 illustrated in FIG. 1B indicates a shape of the second electrode 14 on the lower surface of the second electrode 14, in order to facilitate understanding of a relationship between the lower surface of the second electrode 14 and the OA portion (region P1).

The first electrode 13 and the second electrode 14 are formed by, for example, the same electrode material. The electrode material includes, for example, a seed metal layer, a barrier metal layer, and a plating metal layer in this order. The seed metal layer is, for example, a titanium (Ti) layer, a titanium nitride (TiN) layer, or a titanium tungsten (TiW) layer. A thickness of the seed metal layer is, for example, 2 to 500 nm. The barrier metal layer is, for example, a nickel (Ni) layer. A thickness of the barrier metal layer is, for example, 2 to 500 nm. The plating metal layer is, for example, a copper (Cu) layer. The plating metal layer is formed so as to fill a hole for the first electrode 13 and a hole for the second electrode 14. The first electrode 13 and the second electrode 14 of the present embodiment are formed by a damascene method in which the above-described electrode material is formed in these holes, and a surface of the above-described electrode material is planarized by a chemical mechanical polishing (CMP) method.

### Regrowth Interface S1, Plane S2

FIGS. 1A and 1B further illustrate a regrowth interface S1 and a plane S2. The regrowth interface S1 is formed at an interface between the active layer 4 and the second current injection layer 5. The plane S2 is located at a height of an upper surface of the insulating film 12. Further details of the plane S2 will be described below.

The first electrode 13 and the second electrode 14 of the present embodiment are separated from each other by the second DBR 6 and the insulating film 12, which are formed between the first electrode 13 and the second electrode 14. That is, the first electrode 13 and the second electrode 14 are not in contact with each other, and an insulating film (the second DBR 6 and the insulating film 12) is formed in a region between the first electrode 13 and the second electrode 14.

In FIG. 1A, the plane S2 is the uppermost surface of the light emitting device of the present embodiment and, is perpendicular to the Z direction. The plane S2 of the present embodiment is formed by the upper surface of the insulating film 12, an upper surface of the first electrode 13, and an upper surface of the second electrode 14. Therefore, in the present embodiment, the upper surface of the insulating film 12, the upper surface of the first electrode 13, and the upper surface of the second electrode 14 are located in the same plane (that is, in the plane S2). Therefore, according to the present embodiment, it is possible to achieve suitable bonding between the substrate 1 and another substrate by performing wafer bonding on the plane S2. In FIG. 1A, the uppermost surface of the light emitting device of the present embodiment is planarized by the CMP method to become the plane S2.

In the present embodiment, the upper surface of the insulating film 12 occupies a large portion in the plane S2. Therefore, a ratio of the upper surface of the insulating film 12 to the plane S2 is larger than a ratio of the upper surfaces of the first electrode 13 and the second electrode 14 to the plane S2. These upper surfaces are examples of surfaces on a side opposite to the first substrate in the present disclosure.

Here, a photocurrent constriction structure of the present embodiment will be described.

In order to efficiently oscillate the light emitting element, a photocurrent constriction structure is required. The light emitting device of the present embodiment includes a step of about several nm at the regrowth interface S1, for example, in order to achieve light constriction. As a result, in a region having the step, an effective refractive index is increased as compared with a periphery thereof, and light can be constricted. Furthermore, the light emitting device of the present embodiment includes the implantation region 11 as a current constriction region in order to achieve current constriction.

However, as long as the photocurrent constriction can be achieved, the photocurrent constriction or the current constriction may be achieved by a method different from the above-described method. For example, the current constriction may be achieved by a buried tunnel junction (TJ), or a QWI in which a band gap energy difference is provided between an aperture portion and an outside thereof by Ga vacancy diffusion to confine carriers. Furthermore, light constriction may be achieved by forming a vacancy around a predetermined region and increasing an effective refractive index inside the predetermined region. Furthermore, the photocurrent constriction structure may be achieved by forming a through hole in the aluminum arsenide (AlAs) layer and performing steam oxidation on the AlAs layer from the through hole.

FIGS. 2 to 7 are cross-sectional views and plan views illustrating a method for manufacturing the light emitting device of the first embodiment.

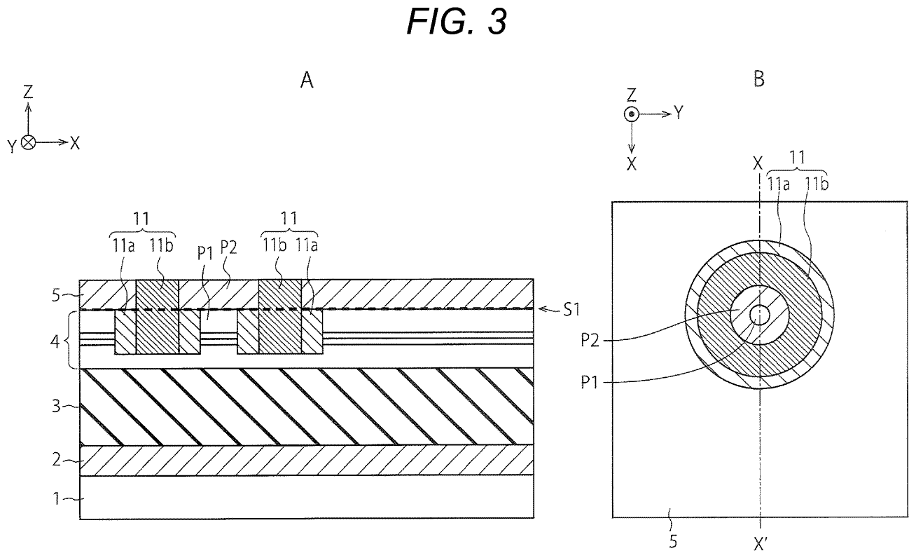

Similarly to FIG. 1A, FIG. 2A is a cross-sectional view illustrating an XZ cross section of the light emitting device of the present embodiment. FIG. 2A illustrates the XZ cross section taken along line X-X′ illustrated in FIG. 2B. Similarly to FIG. 1B, FIG. 2B is a plan view illustrating the light emitting device of the present embodiment as viewed from above. This similarly applies to FIGS. 3A to 7B.

### FIG. 2

First, the substrate 1 is prepared, and the first current injection layer 2, the first DBR 3, and the active layer 4 are sequentially epitaxially grown on the substrate 1 at 605° C. by, for example, a metal organic chemical vapor deposition (MOCVD) method (FIGS. 2A and 2B). Note that these growth layers may be formed by a method other than the MOCVD method, as long as layers similar to those in the case of using the MOCVD method can be formed.

The quantum well layer and the barrier layer in the active layer 4 are formed to contain, for example, aluminum (Al), indium (In), gallium (Ga), and arsenic (As). The Al source gas is, for example, trimethylaluminum ((CH₃)₃Al). The In source gas is, for example, trimethylindium ((CH₃)₃In). The Ga source gas is, for example, trimethylgallium ((CH₃)₃Ga). The As source gas is, for example, trimethylarsine ((CH₃)₃As).

Next, the first implantation region 11a is formed in the active layer 4 by ion implantation into the active layer 4 (FIGS. 2A and 2B). FIGS. 2A and 2B illustrate the region P1 surrounded by the first implantation region 11a. Next, a step for light constriction is formed by wet etching.

### FIG. 3

Next, the second current injection layer 5 is epitaxially grown on the active layer 4 at, for example, 605° C. by the MOCVD method (FIGS. 3A and 3B).

Next, the second implantation region 11b is formed in the active layer 4 and the second current injection layer 5, by ion implantation into the active layer 4 and the second current injection layer 5 (FIGS. 3A and 3B). The ion implantation here is performed to a depth at which chip separation is performed. Furthermore, the second implantation region 11b is formed at a position overlapping with the first implantation region 11a. FIGS. 3A and 3B illustrate the region P2 surrounded by the second implantation region 11b. In this manner, the implantation region 11 including the first implantation region 11a and the second implantation region 11b is formed.

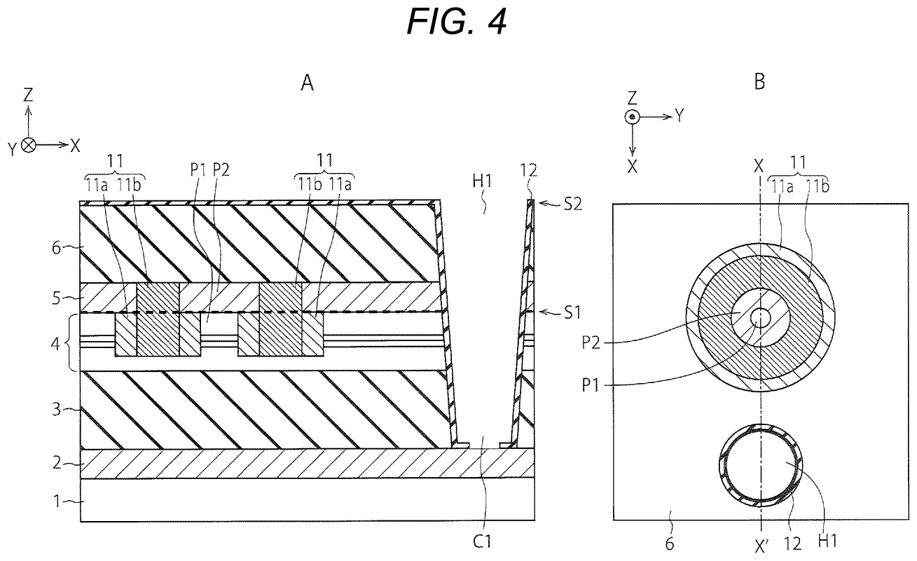

### FIG. 4

Next, the second DBR 6 is formed on the second current injection layer 5 by sputtering or a CVD method (FIGS. 4A and 4B). However, the second DBR 6 may be formed by another method (for example, vapor deposition).

Next, a resist coating film (not illustrated) is formed on the second DBR 6, and a first through hole Hl penetrating the second DBR 6, the second current injection layer 5, the active layer 4, and the first DBR 3 is formed by lithography and dry etching using the resist coating film (FIGS. 4A and 4B). The first through hole H1 is formed so as to reach, for example, the upper surface of the first current injection layer 2. Dry etching for forming the first through hole H1 is, for example, a reactive ion etching (RIE) method. Thereafter, the resist coating film described above is removed.

Next, the insulating film 12 is formed on a side surface and a bottom surface of the first through hole H1 and the upper surface of the second DBR 6, by sputtering or the CVD method (FIGS. 4A and 4B). Next, the insulating film 12 is removed from the bottom surface of the first through hole H1 by dry etching or wet etching, to form the opening C1 in the insulating film 12 (FIGS. 4A and 4B). The dry etching described above is, for example, the RIE method. The wet etching described above is performed using, for example, a hydrogen fluoride (HF) aqueous solution. In FIG. 4B, in order to make a position of the first through hole H1 easily visible, an outline of the first through hole H1 after the insulating film 12 is formed is indicated by a thick line.

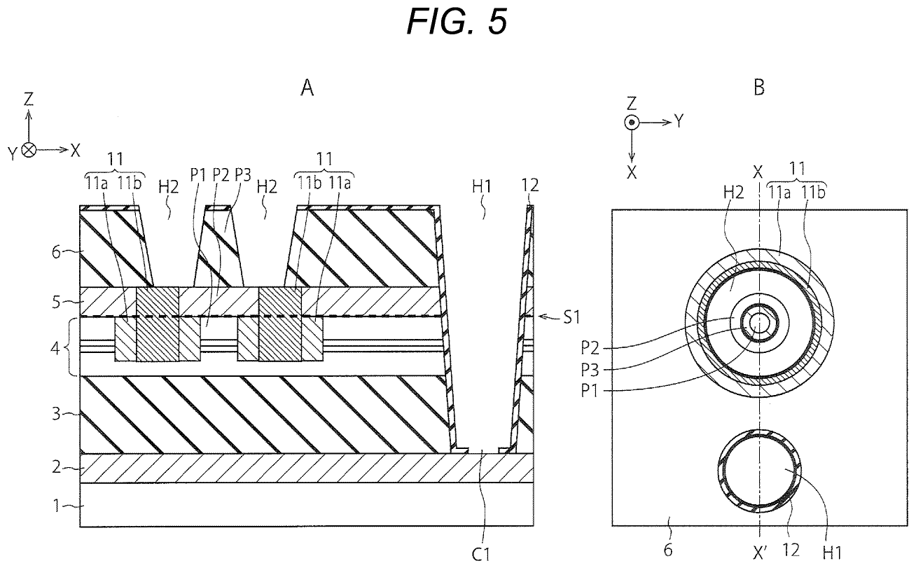

### FIG. 5

Next, a resist coating film (not illustrated) is formed on the second DBR 6, and a second through hole H2 penetrating the second DBR 6 is formed by lithography and dry etching using the resist coating film (FIGS. 5A and 5B). The second through hole H2 is formed so as to reach, for example, the upper surface of the second current injection layer 5. The dry etching for forming the second through hole H2 is, for example, the RIE method. Thereafter, the resist coating film described above is removed. In FIG. 5B, in order to make a position of the second through hole H2 easily visible, an outline of the second through hole H2 is indicated by a thick line. Furthermore, FIGS. 5A and 5B illustrate the region P3 surrounded by the second through hole H2.

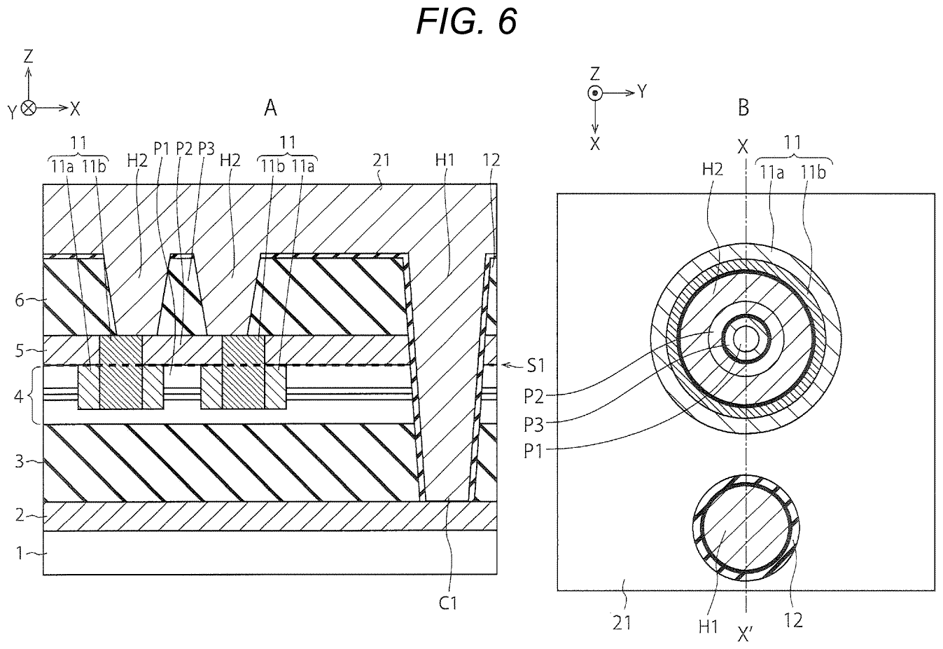

### FIG. 6

Next, an electrode material 21 is formed on the second DBR 6 (FIGS. 6A and 6B). As a result, the electrode material 21 is formed inside and outside the first through hole H1 and the second through hole H2. The electrode material 21 is formed by sequentially forming the seed metal layer, the barrier metal layer, and the plating metal layer described above on the second DBR 6. The seed metal layer is formed by, for example, a vacuum vapor deposition method or sputtering. The barrier metal layer is formed by, for example, the vacuum vapor deposition method or sputtering. The plating metal layer is formed by, for example, a plating method.

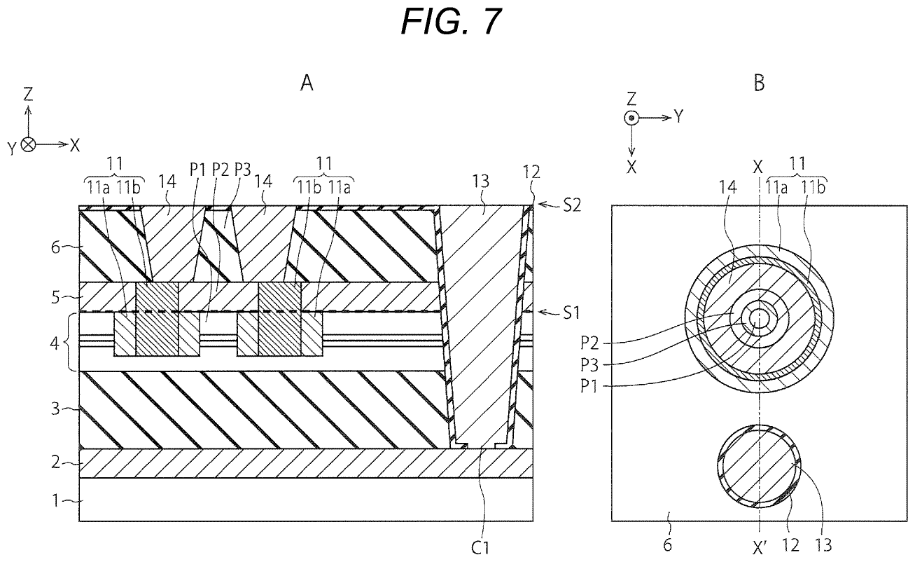

### FIG. 7

Next, an upper surface of the electrode material 21 is planarized by the CMP method (FIGS. 7A and 7B). As a result, the electrode material 21 is removed from the outside of the first through hole H1 and the second through hole H2, and the electrode material 21 remains inside the first through hole H1 and the second through hole H2. The electrode material 21 remaining in the first through hole H1 becomes the first electrode 13, and the electrode material 21 remaining in the second through hole H2 becomes the second electrode 14. Since the first electrode 13 is formed so as to be in contact with the first current injection layer 2 via the opening C1, the first electrode 13 is electrically connected to the first current injection layer 2. Since the second electrode 14 is formed so as to be in contact with the second current injection layer 5, the second electrode 14 is electrically connected to the second current injection layer 5.

The above-described CMP method is performed until the upper surface of the insulating film 12 is exposed from the electrode material 21. Therefore, the first electrode 13 and the second electrode 14 illustrated in FIG. 7A are separated from each other by the second DBR 6 and the insulating film 12. Moreover, the upper surface of the insulating film 12, the upper surface of the first electrode 13, and the upper surface of the second electrode 14 illustrated in FIG. 7A are located in the same plane (that is, in the plane S2).

Thereafter, the lower surface (back surface) of the substrate 1 is ground and mirror-finished, to form an AR coating film on the lower surface of the substrate 1. In this way, the light emitting device illustrated in FIG. 1 is manufactured.

As described above, in the light emitting device of the present embodiment, the upper surface of the insulating film 12, the upper surface of the first electrode 13, and the upper surface of the second electrode 14 are located in the same plane (that is, in the plane S2). Therefore, according to the present embodiment, it is possible to achieve suitable bonding of the substrate 1 for a light emitting element.

Hereinafter, second to thirteenth embodiments will be described. In the following description, matters common to the first embodiment and the second to thirteenth embodiments will be omitted as appropriate.

### Second Embodiment

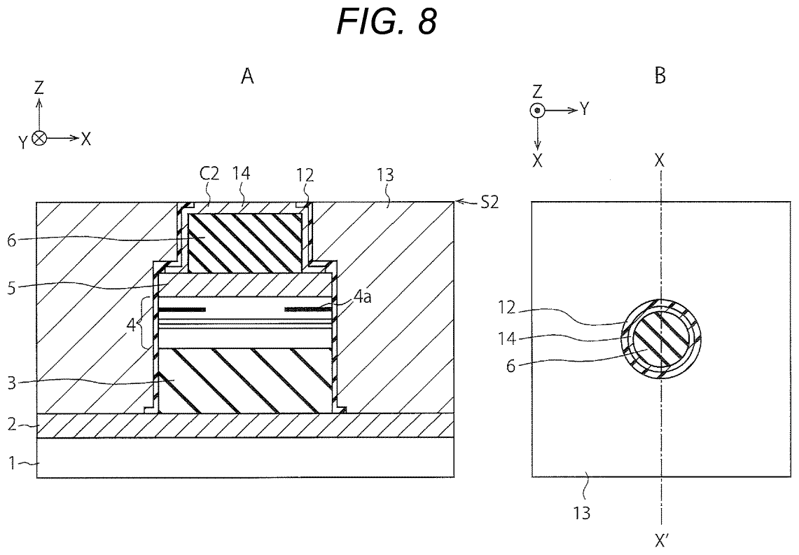

FIG. 8 is a cross-sectional view and a plan view illustrating a structure of a light emitting device of the second embodiment.

As illustrated in FIGS. 8A and 8B, the light emitting device of the present embodiment includes components similar to those of the light emitting device of the first embodiment. However, the light emitting device of the present embodiment does not include the implantation region 11, and instead includes a constriction layer 4a in an active layer 4. The constriction layer 4a is an example of a current constriction region of the present disclosure. Note that, the constriction layer 4a may be provided outside the active layer 4, for example, in a second DBR 6, in a first DBR 3, or in a second current injection layer 5.

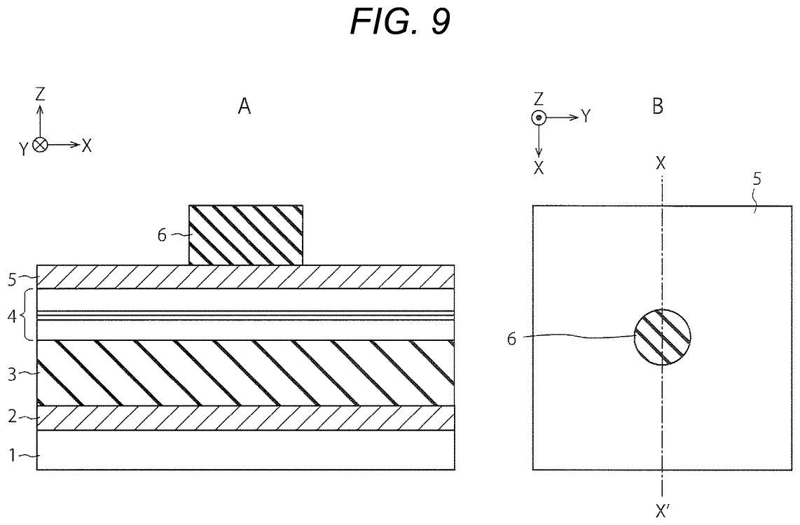

FIG. 8A is a cross-sectional view illustrating an XZ cross section of the light emitting device of the present embodiment. FIG. 8A illustrates the XZ cross section taken along line X-X′ illustrated in FIG. 8B. FIG. 8B is a plan view illustrating the light emitting device of the present embodiment as viewed from above. However, in order to describe a positional relationship among the second DBR 6, an insulating film 12, a first electrode 13, and a second electrode 14, FIG. 8B illustrates a structure of the light emitting device at a height of an XY cross section passing through the second DBR 6, the insulating film 12, the first electrode 13, and the second electrode 14. This similarly applies to FIGS. 9 to 14 described later.

A light emitting element of the present embodiment has a structure of a mesa type. In FIG. 8A, one mesa including the first DBR 3, the active layer 4, the second current injection layer 5, and the second DBR 6 is included in one light emitting element. Similarly to the implantation region 11 of the first embodiment, the constriction layer 4a of the present embodiment has a ring shape in plan view, and a region surrounded in a ring shape by the constriction layer 4a is an OA portion. The constriction layer 4a is formed, for example, by performing steam oxidation on an AlAs layer. In this case, the constriction layer 4a is to be an oxide film. The first DBR 3 of the present embodiment includes, for example, a GaAs layer and an AlGaAs layer. The active layer 4 of the present embodiment includes, for example, an AlAs layer.

In the present embodiment, the second electrode 14 is formed on an upper surface and a side surface of the second DBR 6 and an upper surface of the second current injection layer 5. Furthermore, the insulating film 12 is formed on the upper surface and the side surface of the second DBR 6 and the upper surface of the second current injection layer 5 with the second electrode 14 interposed in between. The insulating film 12 is further formed on side surfaces of the first DBR 3, the active layer 4, and the second current injection layer 5. The insulating film 12 of the present embodiment has an opening C2 that exposes an upper surface of the second electrode 14. As illustrated in FIGS. 8A and 8B, the insulating film 12 of the present embodiment has a shape surrounding the mesa and the second electrode 14 in plan view.

Moreover, in the present embodiment, the first electrode 13 is formed on the side surfaces of the first DBR 3, the active layer 4, the second current injection layer 5, and the second DBR 6 with the second electrode 14 and the insulating film 12 interposed in between. Therefore, the first electrode 13 of the present embodiment is formed on the side surface of the second electrode 14 with the insulating film 12 interposed in between. As illustrated in FIGS. 8A and 8B, the first electrode 13 of the present embodiment has a shape surrounding the mesa, the second electrode 14, and the insulating film 12 in plan view.

The first electrode 13 and the second electrode 14 of the present embodiment are separated from each other by the insulating film 12 formed between the first electrode 13 and the second electrode 14. That is, the first electrode 13 and the second electrode 14 are not in contact with each other, and the insulating film 12 is formed in a region between the first electrode 13 and the second electrode 14.

In FIG. 8A, a plane S2 is the uppermost surface of the light emitting device of the present embodiment and, is perpendicular to the Z direction. The plane S2 of the present embodiment is formed by an upper surface of the insulating film 12, an upper surface of the first electrode 13, and the upper surface of the second electrode 14. Therefore, in the present embodiment, the upper surface of the insulating film 12, the upper surface of the first electrode 13, and the upper surface of the second electrode 14 are located in the same plane (that is, in the plane S2). Therefore, according to the present embodiment, it is possible to achieve suitable bonding between a substrate 1 and another substrate by performing wafer bonding on the plane S2. The insulating film 12 of the present embodiment is an example of a first insulating film of the present disclosure. In FIG. 8A, the uppermost surface of the light emitting device of the present embodiment is planarized by the CMP method to become the plane S2.

In the present embodiment, the upper surface of the first electrode 13 occupies a large portion in the plane S2. Therefore, a ratio of the upper surface of the first electrode 13 to the plane S2 is larger than a ratio of the upper surfaces of the insulating film 12 and the second electrode 14 to the plane S2.

FIGS. 9 to 14 are cross-sectional views and plan views illustrating a method for manufacturing the light emitting device of the second embodiment.

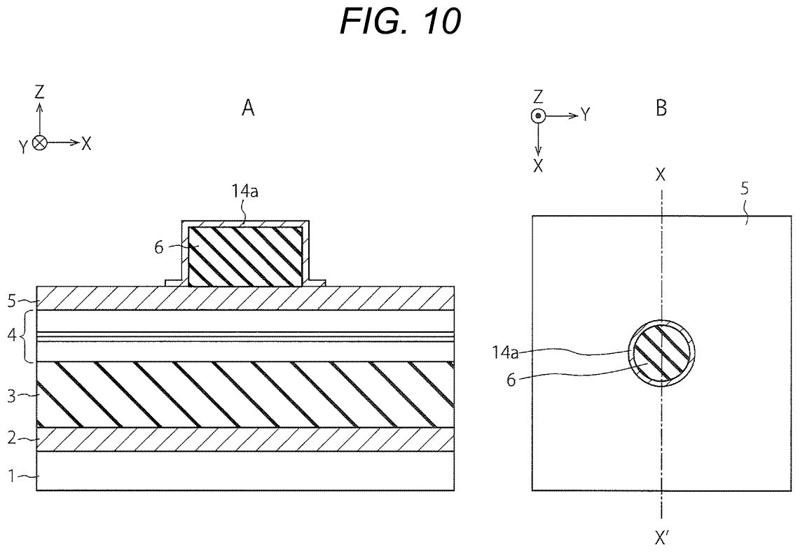

Similarly to FIG. 8A, FIG. 9A is a cross-sectional view illustrating an XZ cross section of the light emitting device of the present embodiment. FIG. 9A illustrates the XZ cross section taken along line X-X′ illustrated in FIG. 9B. Similarly to FIG. 8B, FIG. 9B is a plan view illustrating the light emitting device of the present embodiment as viewed from above. This similarly applies to FIGS. 10A to 14B.

First, a first current injection layer 2, the first DBR 3, the active layer 4, and the second current injection layer 5 are sequentially formed on the substrate 1 by the MOCVD method (FIGS. 9A and 9B). Next, the second DBR 6 is formed on the second current injection layer 5 by sputtering, the CVD method, or vapor deposition (FIGS. 9A and 9B). Next, the second DBR 6 is processed into a mesa shape by lithography and the RIE method (FIGS. 9A and 9B).

Next, a lower layer 14a, which is a part of the second electrode 14, is formed on the upper surface and the side surface of the second DBR 6 and the upper surface of the second current injection layer 5 (FIGS. 10A and 10B).

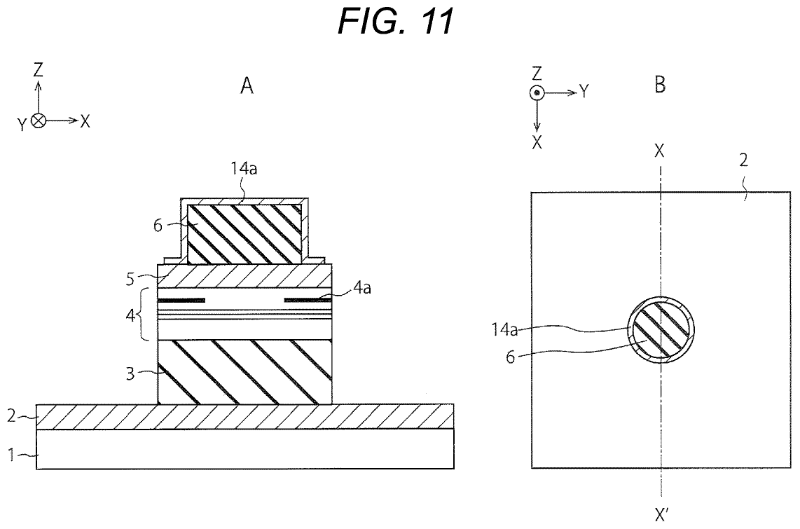

Next, the second current injection layer 5, the active layer 4, and the first DBR 3 are processed into a mesa shape by lithography and the RIE method (FIGS. 11A and 11B). Next, the constriction layer 4a is formed in the active layer 4 (FIGS. 11A and 11B). The constriction layer 4a is formed by oxidizing the AlAs layer in the active layer 4 by, for example, a water vapor oxidation method. The constriction layer 4a of the present embodiment is formed to have, for example, a ring shape in plan view. The ring shape of the constriction layer 4a is circular shape in the present embodiment, but may be other shapes (for example, a polygonal shape such as a rhombus).

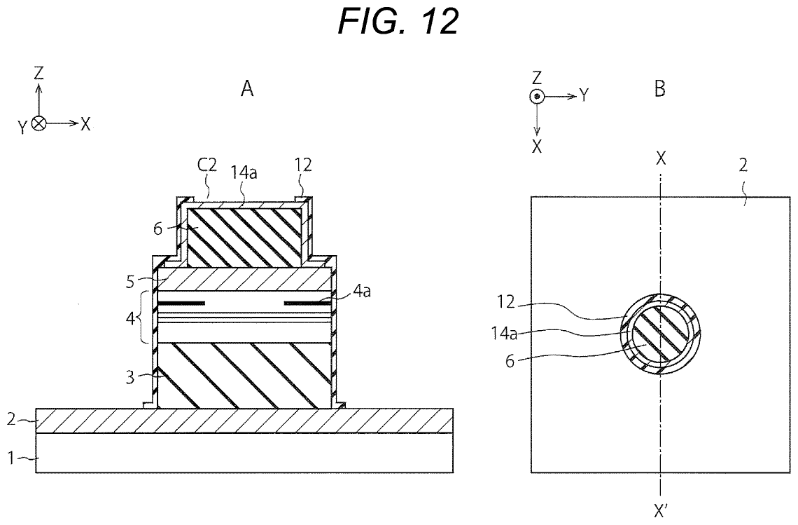

Next, the insulating film 12 is formed on the upper surface and the side surface of the second DBR 6 and the upper surface of the second current injection layer 5 with the lower layer 14a interposed in between, by sputtering or the CVD method (FIGS. 12A and 12B). The insulating film 12 is further formed on the side surfaces of the first DBR 3, the active layer 4, and the second current injection layer 5. Next, the insulating film 12 is removed from an upper surface of the lower layer 14a by lithography and the RIE method, to form the opening C2 in the insulating film 12 (FIGS. 12A and 12B).

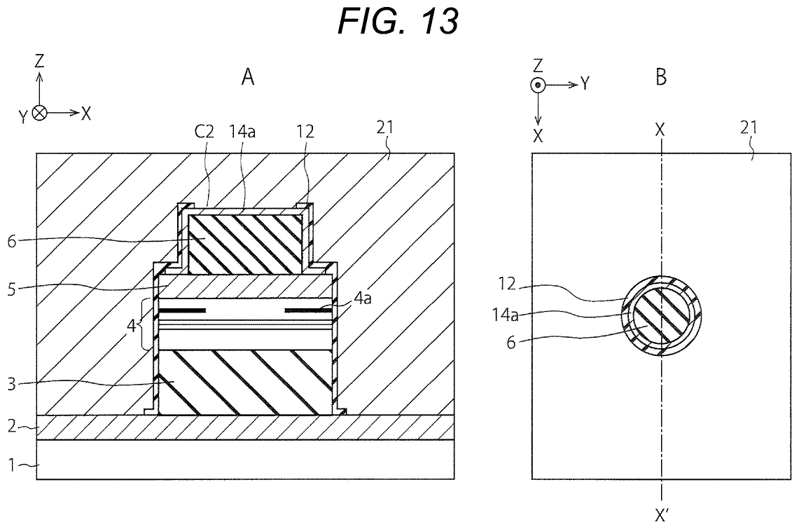

Next, an electrode material 21 is formed on the first current injection layer 2 so as to cover the mesa and the like (FIGS. 13A and 13B). The electrode material 21 of the present embodiment is formed by sequentially forming the seed metal layer, the barrier metal layer, and the plating metal layer described above on the first current injection layer 2.

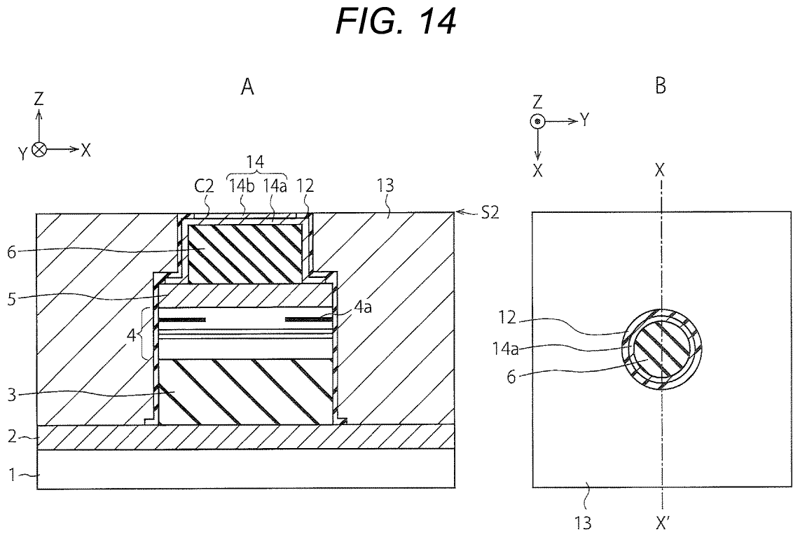

Next, an upper surface of the electrode material 21 is planarized by the CMP method (FIGS. 14A and 14B). As a result, the electrode material 21 remaining on the lower layer 14a becomes an upper layer 14b that is a remainder of the second electrode 14, and the electrode material 21 remaining around the insulating film 12 becomes the first electrode 13. The upper layer 14b is formed in the opening C2 so as to be in contact with the lower layer 14a, and thus is electrically connected to the lower layer 14a.

The above-described CMP method is performed until the upper surface of the insulating film 12 is exposed from the electrode material 21. Therefore, the first electrode 13 and the second electrode 14 illustrated in FIG. 14A are separated from each other by the insulating film 12. Moreover, the upper surface of the insulating film 12, the upper surface of the first electrode 13, and the upper surface of the second electrode 14 illustrated in FIG. 14A are located in the same plane (that is, in the plane S2).

Thereafter, a lower surface (back surface) of the substrate 1 is ground and mirror-finished, to form an AR coating film on the lower surface of the substrate 1. In this way, the light emitting device illustrated in FIG. 8 is manufactured.

As described above, in the light emitting device of the present embodiment, the upper surface of the insulating film 12, the upper surface of the first electrode 13, and the upper surface of the second electrode 14 are located in the same plane (that is, in the plane S2). Therefore, according to the present embodiment, it is possible to achieve suitable bonding of the substrate 1 for a light emitting element.

### Third Embodiment

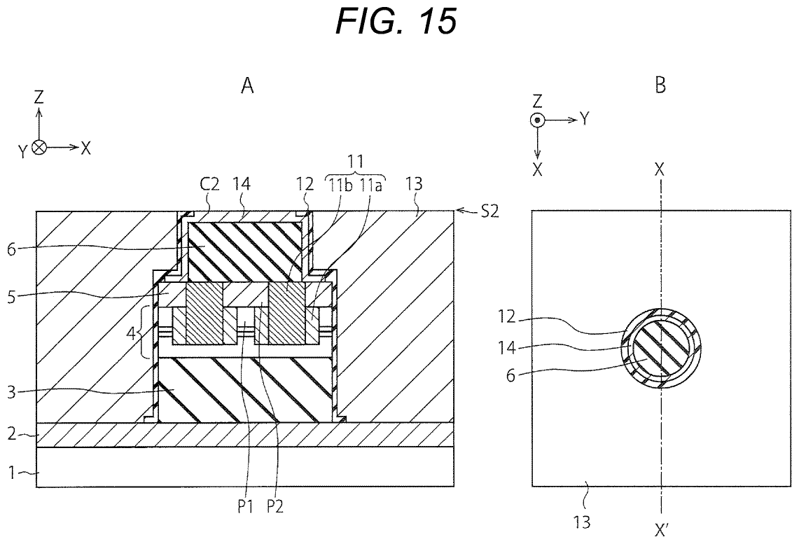

FIG. 15 is a cross-sectional view and a plan view illustrating a structure of a light emitting device of the third embodiment.

As illustrated in FIGS. 15A and 15B, the light emitting device of the present embodiment includes components similar to those of the light emitting device of the second embodiment. However, the light emitting device of the present embodiment includes an implantation region 11 similar to that of the first embodiment, instead of the constriction layer 4a.

FIG. 15A is a cross-sectional view illustrating an XZ cross section of the light emitting device of the present embodiment. FIG. 15A illustrates the XZ cross section taken along line X-X′ illustrated in FIG. 15B. FIG. 15B is a plan view illustrating the light emitting device of the present embodiment as viewed from above. However, in order to describe a positional relationship among a second DBR 6, an insulating film 12, a first electrode 13, and a second electrode 14, FIG. 15B illustrates a structure of the light emitting device at a height of an XY cross section passing through the second DBR 6, the insulating film 12, the first electrode 13, and the second electrode 14.

The light emitting device of the present embodiment can be manufactured, for example, by forming the implantation region 11 instead of the constriction layer 4a in a process illustrated in FIG. 9, at a time of performing the processes illustrated in FIGS. 9 to 14 (the method for manufacturing the light emitting device of the second embodiment). In this case, the implantation region 11 can be formed by, for example, the processes illustrated in FIGS. 2 and 3.

According to the present embodiment, similarly to the second embodiment, it is possible to achieve suitable bonding of a substrate 1 for a light emitting element.

### Fourth Embodiment

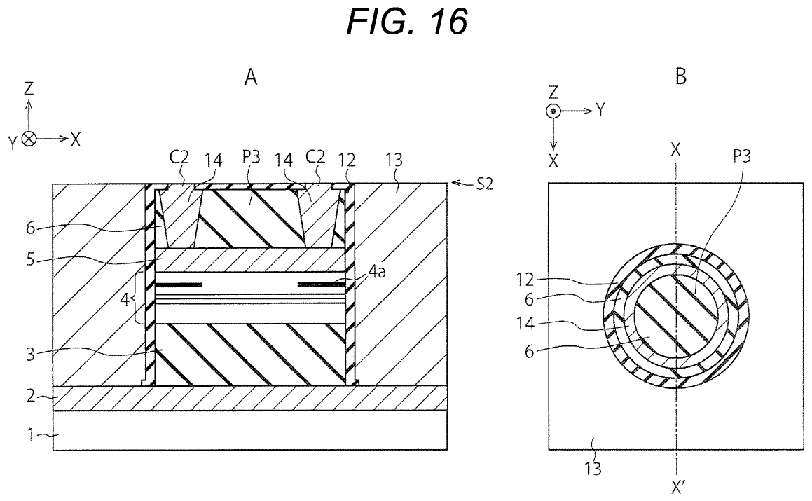

FIG. 16 is a cross-sectional view and a plan view illustrating a structure of a light emitting device of the fourth embodiment.

As illustrated in FIGS. 16A and 16B, the light emitting device of the present embodiment includes components similar to those of the light emitting device of the second embodiment. However, a second electrode 14 of the present embodiment has a ring shape in plan view, similarly to the second electrode 14 of the first embodiment. FIGS. 16A and 16B illustrate a region P3 surrounded in a ring shape by the second electrode 14. Accordingly, an opening C2 of the present embodiment also has a ring shape in plan view.

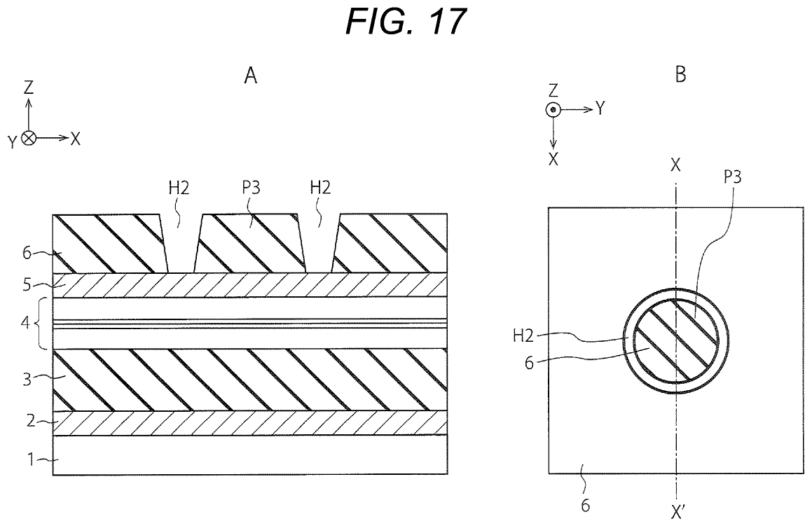

FIG. 16A is a cross-sectional view illustrating an XZ cross section of the light emitting device of the present embodiment. FIG. 16A illustrates the XZ cross section taken along line X-X′ illustrated in FIG. 16B. FIG. 16B is a plan view illustrating the light emitting device of the present embodiment as viewed from above. However, in order to describe a positional relationship among a second DBR 6, an insulating film 12, a first electrode 13, and the second electrode 14, FIG. 16B illustrates a structure of the light emitting device at a height of an XY cross section passing through the second DBR 6, the insulating film 12, the first electrode 13, and the second electrode 14. This similarly applies to FIGS. 17 to 22 described later.

FIGS. 17 to 22 are cross-sectional views and plan views illustrating a method for manufacturing the light emitting device of the fourth embodiment.

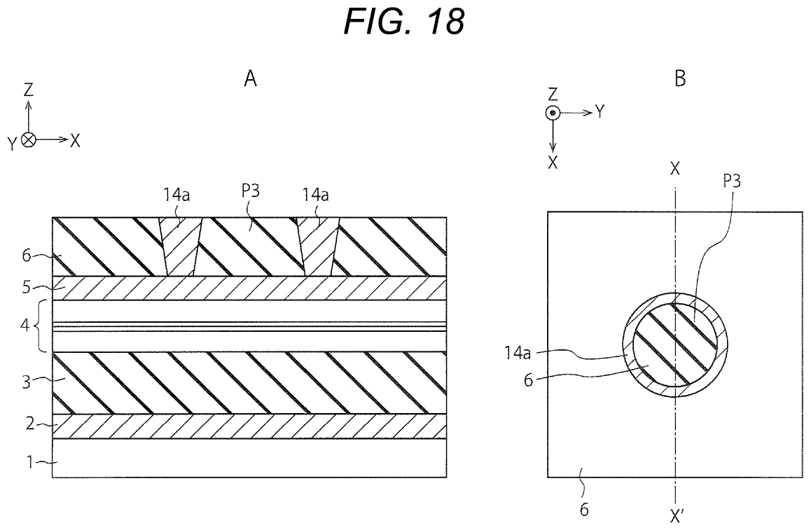

Similarly to FIG. 16A, FIG. 17A is a cross-sectional view illustrating an XZ cross section of the light emitting device of the present embodiment. FIG. 17A illustrates the XZ cross section taken along line X-X′ illustrated in FIG. 16B. Similarly to FIG. 16B, FIG. 17B is a plan view illustrating the light emitting device of the present embodiment as viewed from above. This similarly applies to FIGS. 18A to 22B.

First, a first current injection layer 2, a first DBR 3, an active layer 4, and a second current injection layer 5 are sequentially formed on a substrate 1 by the MOCVD method (FIGS. 17A and 17B). Next, the second DBR 6 is formed on the second current injection layer 5 by sputtering, the CVD method, or vapor deposition (FIGS. 17A and 17B). Next, a second through hole H2 is formed in the second DBR 6 by lithography and the RIE method (FIGS. 17A and 17B). In FIG. 17B, in order to make a position of the second through hole H2 easily visible, an outline of the second through hole H2 is indicated by a thick line. Furthermore, FIGS. 17A and 17B illustrate the region P3 surrounded by the second through hole H2.

Next, a lower layer 14a, which is a part of the second electrode 14, is formed in the second through hole H2 (FIGS. 18A and 18B).

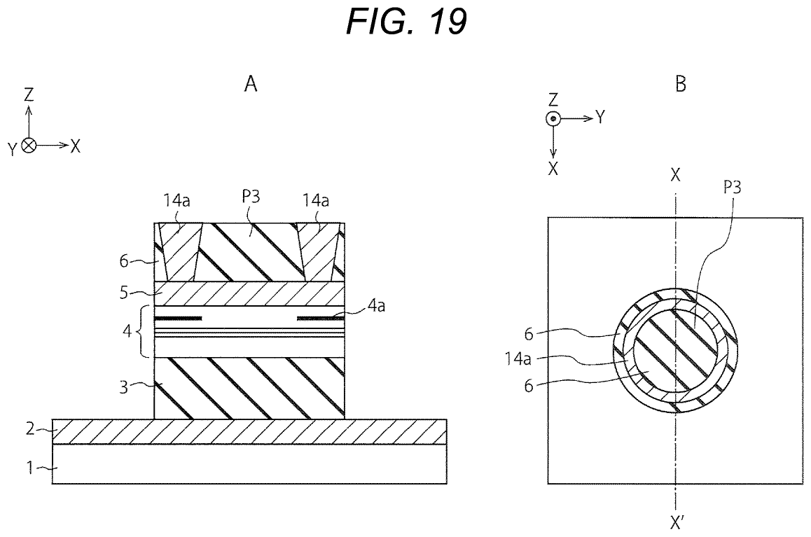

Next, the second DBR 6, the second current injection layer 5, the active layer 4, and the first DBR 3 are processed into a mesa shape by lithography and the RIE method (FIGS. 19A and 19B). Next, a constriction layer 4a is formed in the active layer 4 (FIGS. 19A and 19B). The constriction layer 4a is formed by oxidizing an AlAs layer in the active layer 4 by, for example, the water vapor oxidation method. The constriction layer 4a of the present embodiment is formed to have, for example, a ring shape in plan view.

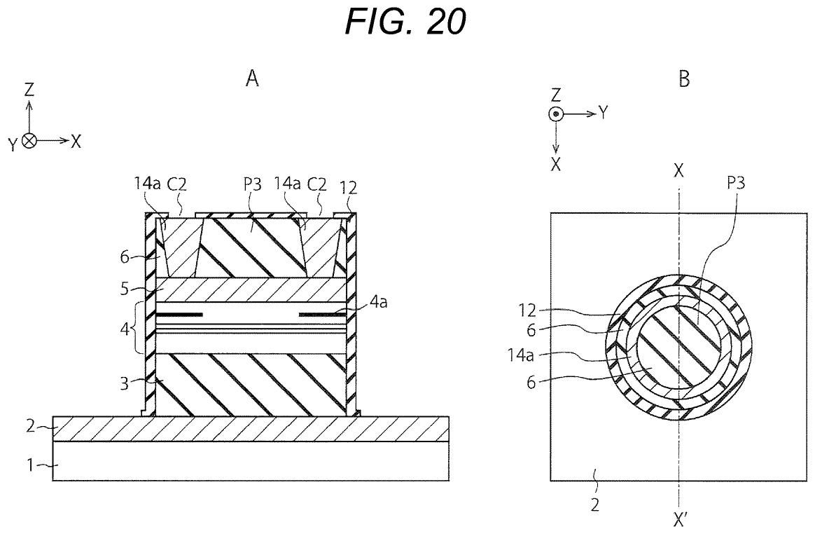

Next, the insulating film 12 is formed on upper surfaces of the second DBR 6 and the lower layer 14a and side surfaces of the first DBR 3, the active layer 4, the second current injection layer 5, and the second DBR 6 by sputtering or the CVD method (FIGS. 20A and 20B). Next, the insulating film 12 is removed from the upper surface of the lower layer 14a and the like by lithography and the RIE method, to form the opening C2 in the insulating film 12 (FIGS. 20A and 20B).

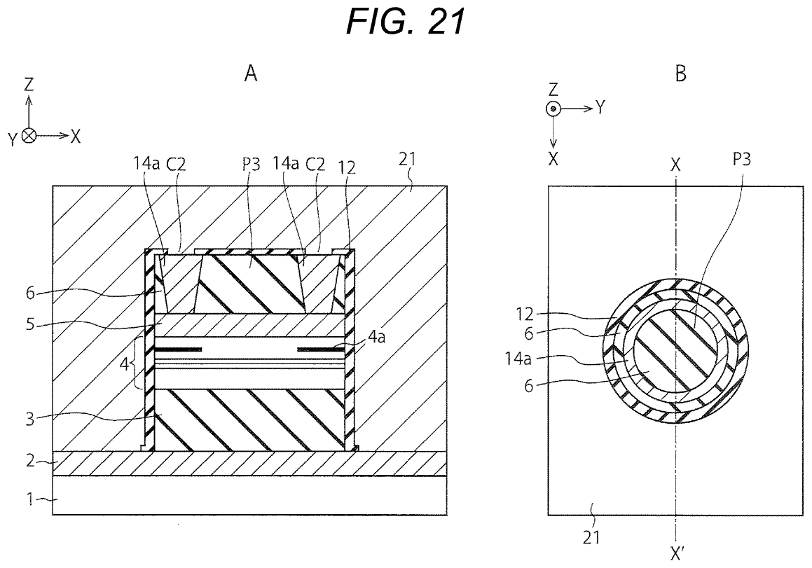

Next, an electrode material 21 is formed on the first current injection layer 2 so as to cover the mesa and the like (FIGS. 21A and 21B). The electrode material 21 of the present embodiment is formed by sequentially forming the seed metal layer, the barrier metal layer, and the plating metal layer described above on the first current injection layer 2.

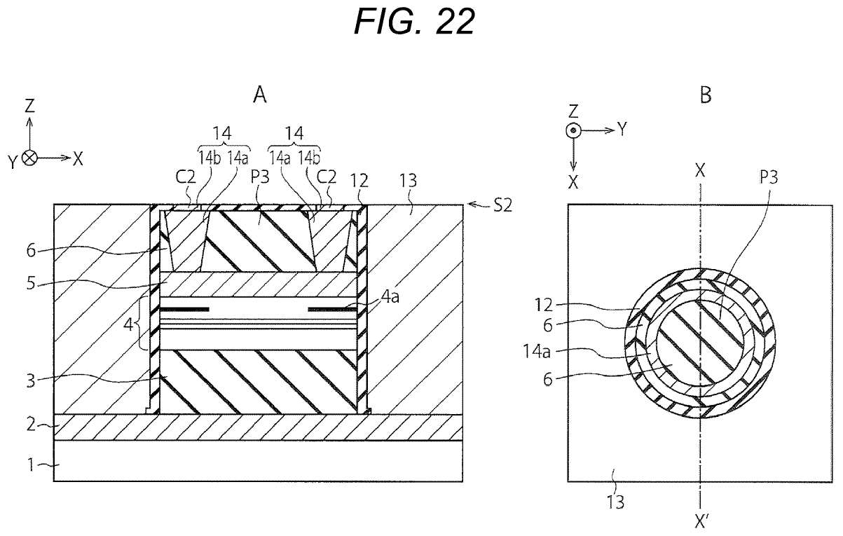

Next, an upper surface of the electrode material 21 is planarized by the CMP method (FIGS. 22A and 22B). As a result, the electrode material 21 remaining on the lower layer 14a becomes an upper layer 14b that is a remainder of the second electrode 14, and the electrode material 21 remaining around the insulating film 12 becomes the first electrode 13. The upper layer 14b is formed in the opening C2 so as to be in contact with the lower layer 14a, and thus is electrically connected to the lower layer 14a.

The above-described CMP method is performed until an upper surface of the insulating film 12 is exposed from the electrode material 21. Therefore, the first electrode 13 and the second electrode 14 illustrated in FIG. 22A are separated from each other by the insulating film 12. Moreover, the upper surface of the insulating film 12, an upper surface of the first electrode 13, and an upper surface of the second electrode 14 illustrated in FIG. 22A are located in the same plane (that is, in a plane S2).

Thereafter, a lower surface (back surface) of the substrate 1 is ground and mirror-finished, to form an AR coating film on the lower surface of the substrate 1. In this way, the light emitting device illustrated in FIG. 16 is manufactured.

According to the present embodiment, similarly to the second and third embodiments, it is possible to achieve suitable bonding of the substrate 1 for a light emitting element. Furthermore, according to the present embodiment, it is possible to obtain an effect similar to the effect obtained by the second electrode 14 of the first embodiment.

### Fifth Embodiment

FIG. 23 is a cross-sectional view illustrating a Structure of a light emitting device of the fifth embodiment.

As illustrated in FIG. 23, the light emitting device of the present embodiment includes components similar to those of the light emitting device of the first embodiment. However, the light emitting device of the present embodiment includes a first DBR 3′ and a second DBR 6′ instead of the first DBR 3 and the second DBR 6. The first DBR 3′ and the second DBR 6′ are, for example, semiconductor layers. Therefore, a second electrode 14 of the present embodiment is formed in the second DBR 6′ with an insulating film 31 interposed in between. The insulating film 31 is, for example, an SiO₂ layer or an SiN layer.

A first electrode 13 and the second electrode 14 of the present embodiment are separated from each other by insulating films 12 and 31 formed between the first electrode 13 and the second electrode 14. That is, the first electrode 13 and the second electrode 14 are not in contact with each other, and the insulating films 12 and 31 are formed in a region between the first electrode 13 and the second electrode 14.

In FIG. 23, a plane S2 is the uppermost surface of the light emitting device of the present embodiment and, is perpendicular to the Z direction. The plane S2 of the present embodiment is formed by upper surfaces of the insulating films 12 and 31, an upper surface of the first electrode 13, and an upper surface of the second electrode 14. Therefore, in the present embodiment, the upper surfaces of the insulating films 12 and 31, the upper surface of the first electrode 13, and the upper surface of the second electrode 14 are located in the same plane (that is, in the plane S2). Therefore, according to the present embodiment, it is possible to achieve suitable bonding between a substrate 1 and another substrate by performing wafer bonding on the plane S2. In FIG. 23, the uppermost surface of the light emitting device of the present embodiment is planarized by the CMP method to become the plane S2. The insulating films 12 and 31 of the present embodiment are examples of a first insulating film of the present disclosure, and the insulating film 31 of the present embodiment is an example of a third insulating film of the present disclosure.

According to the present embodiment, it is possible to obtain an effect similar to the effect obtained by the first embodiment. The light emitting device of the present embodiment can be manufactured similarly to the light emitting device of the first embodiment by replacing the process relating to the first DBR 3 and the second DBR 6 with a process relating to the first DBR 3′ and the second DBR 6′, and adding a process of forming the insulating film 31. Note that, in the present embodiment, the second DBR 6′ may be a semiconductor layer, and the first DBR 3′ may be a conductor layer or an insulating film. In a case where the whole or a part of the first DBR 3′ is an insulating film, a first current injection layer 2 is formed, for example, inside the first DBR 3′ or between the first DBR 3′ and an active layer 4.

### Sixth Embodiment

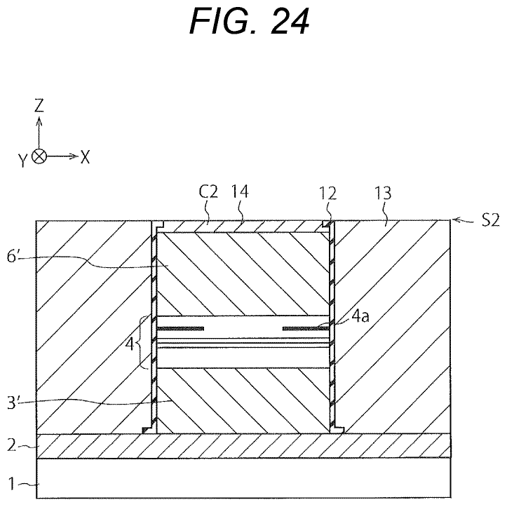

FIG. 24 is a cross-sectional view illustrating a Structure of a light emitting device of the sixth embodiment.

As illustrated in FIG. 24, the light emitting device of the present embodiment includes components similar to those of the light emitting device of the second embodiment. However, instead of the first DBR 3, the second current injection layer 5, and the second DBR 6, the light emitting device of the present embodiment includes a first DBR 3′ and a second DBR 6′. The first DBR 3′ and the second DBR 6′ are, for example, semiconductor layers. The second DBR 6′ of the present embodiment has both the function of the second DBR 6 of the second embodiment and the function of the second current injection layer 5 of the second embodiment. Therefore, a second electrode 14 of the present embodiment is in contact with the second DBR 6′, and is electrically connected to the second DBR 6′.

According to the present embodiment, it is possible to obtain an effect similar to the effect obtained by the second embodiment. The light emitting device of the present embodiment can be manufactured similarly to the light emitting device of the second embodiment, by replacing the process relating to the first DBR 3, the second current injection layer 5, and the second DBR 6 with a process relating to the first DBR 3′ and the second DBR 6′. Note that, in the present embodiment, the second DBR 6′ may be a semiconductor layer, and the first DBR 3′ may be a conductor layer or an insulating film.

In a case where the whole or a part of the first DBR 3′ is an insulating film, a first current injection layer 2 is formed, for example, inside the first DBR 3′ or between the first DBR 3′ and an active layer 4.

### Seventh Embodiment

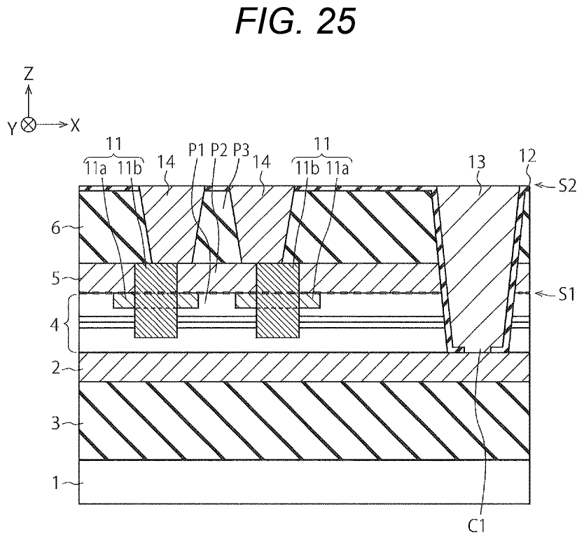

FIG. 25 is a cross-sectional view illustrating a structure of a light emitting device of the seventh embodiment.

As illustrated in FIG. 25, the light emitting device of the present embodiment includes components similar to those of the light emitting device of the first embodiment. However, the light emitting device of the present embodiment has an intra-cavity structure, and specifically includes a first current injection layer 2 between an active layer 4 and a first DBR 3. Therefore, a first electrode 13 of the present embodiment does not penetrate the first DBR 3. Note that the first current injection layer 2 of the present embodiment may be provided at a position different from the position illustrated in FIG. 25.

According to the present embodiment, it is possible to obtain an effect similar to the effect obtained by the first embodiment.

### Eighth Embodiment

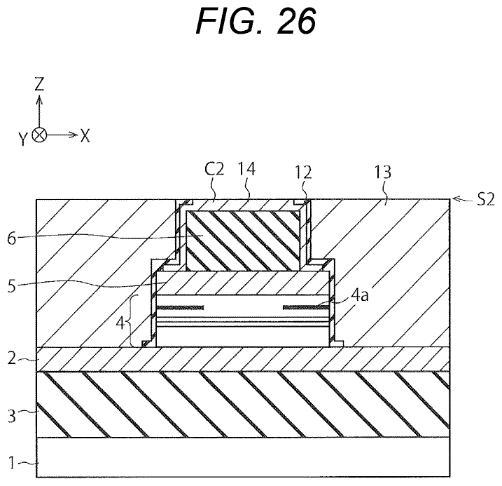

FIG. 26 is a cross-sectional view illustrating a Structure of a light emitting device of the eighth embodiment.

As illustrated in FIG. 26, the light emitting device of the present embodiment includes components similar to those of the light emitting device of the second embodiment. However, the light emitting device of the present embodiment has an intra-cavity structure, and specifically includes a first current injection layer 2 between an active layer 4 and a first DBR 3. Therefore, a mesa of the present embodiment does not include the first DBR 3. Note that the first current injection layer 2 of the present embodiment may be provided at a position different from the position illustrated in FIG. 26. For example, the first current injection layer 2 may be included in the first DBR 3, and a part of the first DBR 3 may be included in the mesa.

According to the present embodiment, it is possible to obtain an effect similar to the effect obtained by the second embodiment.

### Ninth Embodiment

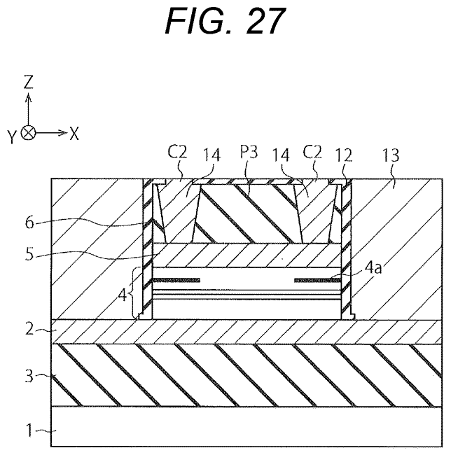

FIG. 27 is a cross-sectional view illustrating a structure of a light emitting device of the ninth embodiment.

As illustrated in FIG. 27, the light emitting device of the present embodiment includes components similar to those of the light emitting device of the fourth embodiment. However, the light emitting device of the present embodiment has an intra-cavity structure, and specifically includes a first current injection layer 2 between an active layer 4 and a first DBR 3. Therefore, a mesa of the present embodiment does not include the first DBR 3. Note that the first current injection layer 2 of the present embodiment may be provided at a position different from the position illustrated in FIG. 27.

According to the present embodiment, it is possible to obtain an effect similar to the effect obtained by the fourth embodiment.

### Tenth Embodiment

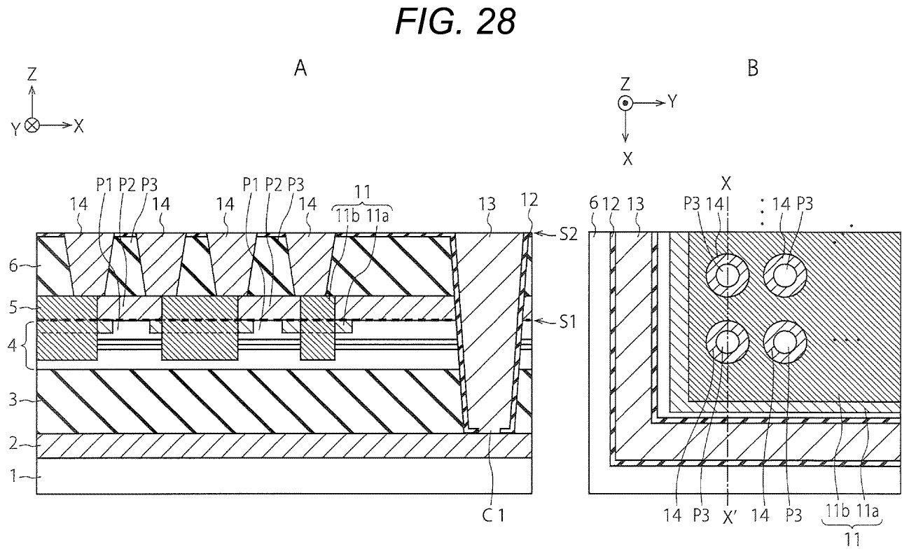

FIG. 28 is a cross-sectional view and a plan view illustrating a structure of a light emitting device of the tenth embodiment.

As illustrated in FIGS. 28A and 28B, the light emitting device of the present embodiment includes components similar to those of the light emitting device of the first embodiment. However, the light emitting device of the present embodiment includes an implantation region 11, an insulating film 12, a first electrode 13, and a plurality of second electrodes 14, with a shape and arrangement different from those of the first embodiment. FIGS. 28A and 28B further illustrate a plurality of regions P1 surrounded by a first implantation region 11a, a plurality of regions P2 surrounded by a second implantation region 11b, and a plurality of regions P3 individually surrounded by the plurality of second electrodes 14.

FIG. 28A is a cross-sectional view illustrating an XZ cross section of the light emitting device of the present embodiment. FIG. 28A illustrates the XZ cross section taken along line X-X′ illustrated in FIG. 28B. FIG. 28B is a plan view illustrating the light emitting device of the present embodiment as viewed from above. However, in order to describe a positional relationship between the implantation region 11 and the second electrode 14, FIG. 28B illustrates a structure of the light emitting device at a height of an XY cross section passing through a second DBR 6, the insulating film 12, the first electrode 13, and the second electrode 14, and also illustrates a position of the implantation region 11 covered by the second DBR 6.

While FIGS. 1A and 1B illustrate one light emitting element, FIGS. 28A and 28B illustrate a plurality of light emitting elements. Specifically, FIG. 28B illustrates four second electrodes 14 for four light emitting elements, and FIG. 28A illustrates four cross sections of two second electrodes 14 for two light emitting elements.

Similarly to the light emitting device of the first embodiment, the light emitting device of the present embodiment has a stacked structure including a first current injection layer 2, a first DBR 3, an active layer 4, a second current injection layer 5, and the second DBR 6 in this order on a substrate 1, and the stacked structure forms a plurality of light emitting elements.

The first implantation region 11a of the present embodiment has a quadrangular shape in plan view as illustrated in FIG. 28B, and surrounds the plurality of regions P1 as illustrated in FIG. 28A. Each region P1 functions as an OA portion of one light emitting element. Furthermore, the second implantation region 11b of the present embodiment has a quadrangular shape in plan view as illustrated in FIG. 28B, and surrounds the plurality of regions P2 as illustrated in FIG. 28A. Each region P2 corresponds to one region P1. In the present embodiment, each region P1 has a first inner diameter, and each region P2 has a second inner diameter larger than the first inner diameter.

As illustrated in FIG. 28B, the first electrode 13 of the present embodiment has a ring shape surrounding the implantation region 11 in plan view. FIG. 28B illustrates a part of a ring formed by the first electrode 13. As illustrated in FIG. 28A, the first electrode 13 of the present embodiment is formed in the first DBR 3, the active layer 4, the second current injection layer 5, and the second DBR 6 with the insulating film 12 interposed in between.

Each of the second electrodes 14 of the present embodiment has a ring shape in plan view as illustrated in FIG. 28B, and surrounds one region P3 as illustrated in FIGS. 28A and 28B. Each region P3 corresponds to one region P1 and one region P2. A lower surface of each of the second electrodes 14 of the present embodiment is in contact with a lower surface of the second current injection layer 5 and a lower surface of the implantation region 11, similarly to the lower surface of the second electrode 14 of the first embodiment.

The second electrode 14 of the present embodiment has a one-to-one correspondence with the light emitting element. As illustrated in FIGS. 28A and 28B, the second electrode 14 of each light emitting element of the present embodiment is separated from the second electrode 14 of another light emitting element. These second electrodes 14 are separated from each other by the second DBR 6 (insulating film) or the insulating film 12. In the present embodiment, a plurality of light emitting elements is formed on the substrate 1 in a two-dimensional array (light emitting element array).

In FIG. 28A, a plane S2 is the uppermost surface of the light emitting device of the present embodiment and, is perpendicular to the Z direction. The plane S2 of the present embodiment is formed by an upper surface of the insulating film 12, an upper surface of the first electrode 13, and an upper surface of the second electrode 14. Therefore, in the present embodiment, the upper surface of the insulating film 12, the upper surface of the first electrode 13, and the upper surface of the second electrode 14 are located in the same plane (that is, in the plane S2). Therefore, according to the present embodiment, it is possible to achieve suitable bonding between the substrate 1 and another substrate by performing wafer bonding on the plane S2. In FIG. 28A, the uppermost surface of the light emitting device of the present embodiment is planarized by the CMP method to become the plane S2.

In the present embodiment, the upper surface of the insulating film 12 occupies a large portion in the plane S2. Therefore, a ratio of the upper surface of the insulating film 12 to the plane S2 is larger than a ratio of the upper surfaces of the first electrode 13 and the second electrode 14 to the plane S2.

According to the present embodiment, it is possible to obtain an effect similar to the effect obtained by the first embodiment. Note that each light emitting element in the light emitting element array of the present embodiment may have a structure other than the structure illustrated in FIGS. 28A and 28B, and for example, may have the same structure as the light emitting element of any of the first to ninth embodiments.

### Eleventh Embodiment

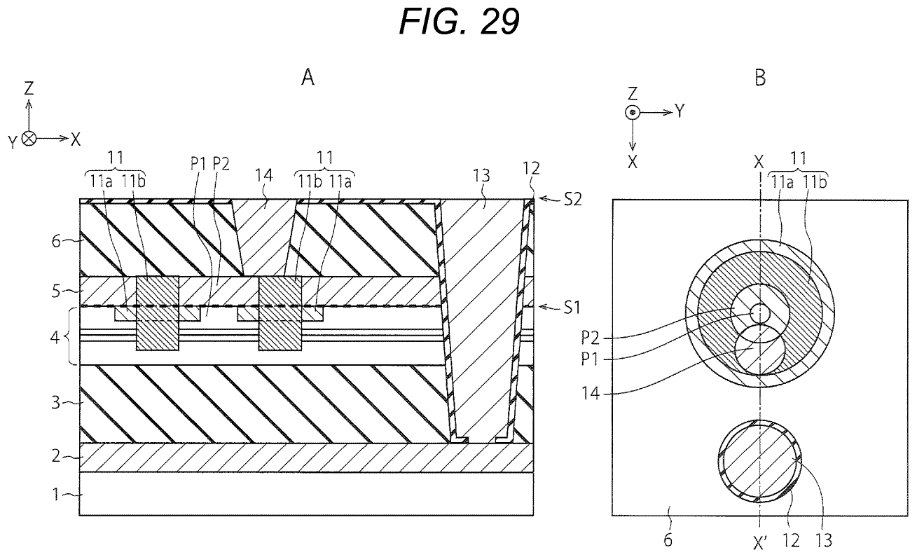

FIG. 29 is a cross-sectional view and a plan view illustrating a structure of a light emitting device of the eleventh embodiment.

As illustrated in FIGS. 29A and 29B, the light emitting device of the present embodiment includes components similar to those of the light emitting device of the first embodiment. However, a second electrode 14 of the present embodiment has a shape different from that of the second electrode 14 of the first embodiment.

FIG. 29A is a cross-sectional view illustrating an XZ cross section of the light emitting device of the present embodiment. FIG. 29A illustrates the XZ cross section taken along line X-X′ illustrated in FIG. 29B. FIG. 29B is a plan view illustrating the light emitting device of the present embodiment as viewed from above. However, in order to describe a positional relationship between the implantation region 11 and the second electrode 14, FIG. 29B illustrates not only positions of an insulating film 12, a first electrode 13, and the second electrode 14 exposed from a second DBR 6 but also a position of the implantation region 11 covered with the second DBR 6.

As illustrated in FIG. 29B, the second electrode 14 of the present embodiment has a non-ring shape in plan view, and specifically, has a circular shape in plan view. As described above, a planar shape of the second electrode 14 can be set to various shapes. For example, the second electrode 14 may have a bar shape extending in the X direction or the Y direction in plan view.

According to the present embodiment, it is possible to obtain an effect similar to the effect obtained by the first embodiment.

### Twelfth Embodiment

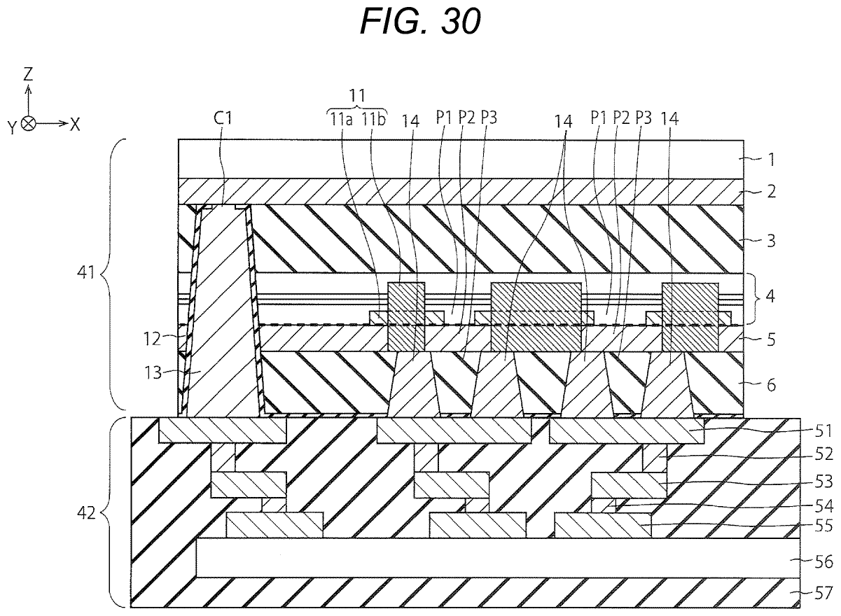

FIG. 30 is a cross-sectional view illustrating a Structure of a light emitting device of the twelfth embodiment.

The light emitting device of the present embodiment includes a laser diode (LD) chip 41 and a laser diode driver (LDD) substrate 42. The LD chip 41 is also referred to as a VCSEL substrate. The LD chip 41 is an example of a light emitting element substrate of the present disclosure. The LDD substrate 42 is an example of a wiring substrate of the present disclosure.

The LD chip 41 has the same structure as the light emitting device of the tenth embodiment. However, the light emitting device of the tenth embodiment illustrated in FIG. 28A is disposed upward, whereas the LD chip 41 illustrated in FIG. 30 is disposed downward. In FIG. 30, the LD chip 41 is bonded to the LDD substrate 42 by wafer bonding on a plane S2 (see FIG. 28A).

The LDD substrate 42 includes, for example, a wiring layer 51, a plurality of via plugs 52, a wiring layer 53, a plurality of via plugs 54, a wiring layer 55, a substrate 56, and an insulating film 57. The wiring layer 51, the via plug 52, the wiring layer 53, the via plug 54, and the wiring layer 55 are formed in the insulating film 57 on the substrate 56, and function as wiring for a light emitting element in the LD chip 41. The substrate 56 is an example of a second substrate of the present disclosure. The LDD substrate 42 further includes a drive circuit (not illustrated) that drives the light emitting element inside the LD chip 41.

A substrate 1 and the substrate 56 of the present embodiment are bonded to each other so as to sandwich an active layer 4 and the like provided on the substrate 1 and the insulating film 57 and the like provided on the substrate 56. The substrate 1 and the substrate 56 of the present embodiment are bonded not by bump bonding in which a metal bump is disposed between the substrate 1 and the substrate 56 but by wafer bonding in which a metal bump is not disposed between the substrate 1 and the substrate 56. Therefore, a first electrode 13 and a second electrode 14 in the LD chip 41 are directly bonded to the wiring layer 51 in the LDD substrate 42 without using a metal bump.

Such bonding can be achieved since a surface of the LD chip 41 is the plane S2. This is because, when the surface of the LD chip 41 is the plane S2 and the surface of the LDD substrate 42 is also a plane, these surfaces can be brought into contact with each other in a wide range. According to the present embodiment, since the surface of the LD chip 41 is the plane S2, the substrate 1 (LD chip 41) and the substrate 56 (LDD substrate 42) can be suitably bonded. Since the first electrode 13 and the second electrode 14 of the present embodiment are exposed on the plane S2, they can be directly bonded to the wiring layer 51 by wafer bonding on the plane S2.

Note that the LD chip 41 may have the same Structure as the light emitting device of any embodiment other than the tenth embodiment. Furthermore, the substrate to be bonded to the LD chip 41 may have a structure different from that of the LDD substrate 42.

### Thirteenth Embodiment

### (1) Configuration of Distance Measuring Device 101

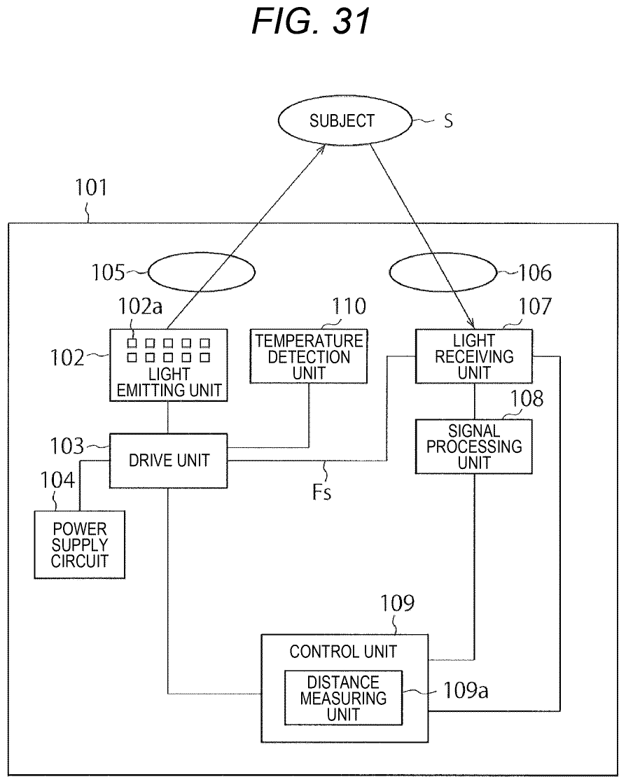

FIG. 31 is a block diagram illustrating a configuration example of a distance measuring device 101 of the thirteenth embodiment. The distance measuring device 101 of the present embodiment is mounted on an automobile, for example.

As illustrated in the figure, the distance measuring device 101 includes a light emitting unit 102, a drive unit 103, a power supply circuit 104, a light-emitting side optical system 105, a light-receiving side optical system 106, a light receiving unit 107, a signal processing unit 108, a control unit 109, and a temperature detection unit 110.

The light emitting unit 102 emits light by a plurality of light sources. The light emitting unit 102 of the present example has a light emitting element 102a by a vertical cavity surface emitting laser (VCSEL) as each light source, and these light emitting elements 102a are disposed in a predetermined mode such as a matrix. The light emitting unit 102 is, for example, the light emitting device according to any one of the first to eleventh embodiments or the LD chip 41 according to the twelfth embodiment.

The drive unit 103 includes a power supply circuit for driving the light emitting unit 102. The drive unit 103 is, for example, the LDD substrate 42 of the twelfth embodiment.

The power supply circuit 104 generates a power supply voltage of the drive unit 103 on the basis of, for example, an input voltage from a battery or the like (not illustrated) provided in the distance measuring device 101. The drive unit 103 drives the light emitting unit 102 on the basis of the power supply voltage.

A subject S as a distance measurement target is irradiated with light emitted from the light emitting unit 102 via the light-emitting side optical system 105. Then, reflected light from the subject S of the light radiated in this manner is incident on a light receiving surface of the light receiving unit 107 via the light-receiving side optical system 106.

The light receiving unit 107 is, for example, a light receiving element such as a charge coupled device (CCD) sensor or a complementary metal oxide semiconductor (CMOS) sensor, receives the reflected light from the subject S incident through the light-receiving side optical system 106 as described above, converts the reflected light into an electrical signal, and outputs the electrical signal.

The light receiving unit 107 performs, for example, correlated double sampling (CDS) processing, automatic gain control (AGC) processing, or the like on an electrical signal obtained by executing photoelectric conversion on received light, and also performs analog/digital (A/D) conversion processing. Then, the signal as digital data is output to the signal processing unit 108 in the subsequent stage.

Furthermore, the light receiving unit 107 of the present example outputs a frame synchronization signal Fs to the drive unit 103. Thus, the drive unit 103 can cause the light emitting elements 102a in the light emitting unit 102 to emit light at a timing corresponding to a frame period of the light receiving unit 107.

The signal processing unit 108 is configured as a signal processing processor by, for example, a digital signal processor (DSP) or the like. The signal processing unit 108 performs various types of signal processing on the digital signal input from the light receiving unit 107.

The control unit 109 includes, for example, a microcomputer including a central processing unit (CPU), a read only memory (ROM), a random access memory (RAM), and the like, or an information processing device such as a DSP, and performs control of the drive unit 103 for controlling a light emission operation by the light emitting unit 102 and control related to a light reception operation by the light receiving unit 107.

The control unit 109 has a function as a distance measuring unit 109a. The distance measuring unit 109a measures a distance to the subject S on the basis of a signal input via the signal processing unit 108 (that is, a signal obtained by receiving reflected light from the subject S). The distance measuring unit 109a of the present example measures a distance for each part of the subject S in order to enable identification of a three-dimensional shape of the subject S.

Here, a specific method for distance measurement in the distance measuring device 101 will be described again later.

The temperature detection unit 110 detects a temperature of the light emitting unit 102. As the temperature detection unit 110, for example, a configuration can be adopted in which temperature detection is performed using a diode.

In the present example, information about the temperature detected by the temperature detection unit 110 is supplied to the drive unit 103, whereby the drive unit 103 can drive the light emitting unit 102 on the basis of the information about the temperature.

### (2) Distance Measuring Method

As a distance measuring method in the distance measuring device 101, for example, a distance measuring method by a structured light (STL) method or a time of flight (ToF) method can be adopted.

The STL method is a method for measuring a distance on the basis of an image of the subject S irradiated with light having a predetermined light/dark pattern such as a dot pattern or a lattice pattern.

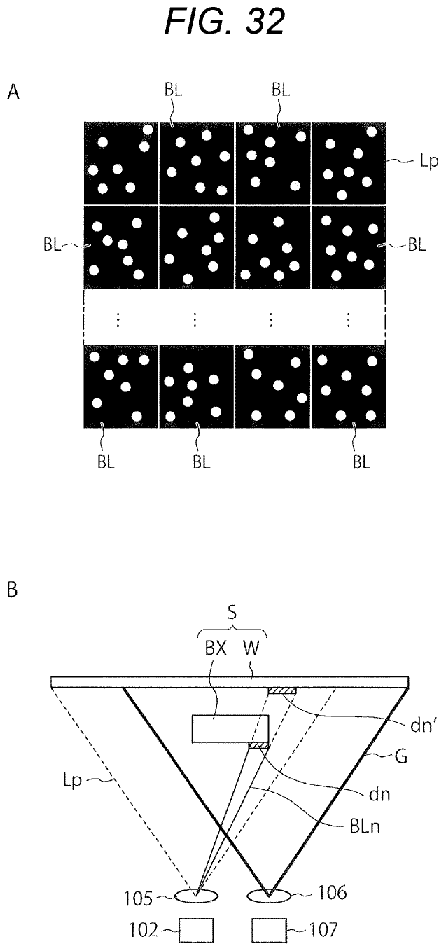

FIG. 32 is a diagram for explaining the STL method of the thirteenth embodiment.

In the STL method, for example, the subject S is irradiated with pattern light Lp by a dot pattern as illustrated in A of FIG. 32A. The pattern light Lp is divided into a plurality of blocks BL, and different dot patterns are allocated to the respective blocks BL (the dot patterns do not overlap between the blocks B).

FIG. 32B is an explanatory diagram of the distance measurement principle of the STL method.

Here, an example is used in which a wall W and a box BX disposed in front of the wall W are the subject S, and the subject S is irradiated with the pattern light Lp. “G” in the figure schematically represents an angle of view by the light receiving unit 107.

Furthermore, “BLn” in the figure means light of a certain block BL in the pattern light Lp, and “dn” means a dot pattern of the block BLn projected on the light receiving image by the light receiving unit 107.

Here, in a case where the box BX in front of the wall W does not exist, the dot pattern of the block BLn is projected at the position of “dn′” in the figure in the light receiving image. That is, the position at which the pattern of the block BLn is projected in the light receiving image is different between the case where the box BX exists and the case where the box BX does not exist, and specifically, pattern distortion occurs.

The STL method is a method for obtaining a shape and a depth of the subject S by using the fact that the pattern irradiated in this manner is distorted according to the object shape of the subject S. Specifically, the STL method is a method for obtaining the shape and the depth of the subject S from the way of the pattern distortion.

In the case of adopting the STL method, for example, an infrared (IR) light receiving unit by a global shutter method is used as the light receiving unit 107. Then, in the case of the STL method, the distance measuring unit 109a controls the drive unit 103 so that the light emitting unit 102 emits pattern light, detects the pattern distortion for the image signal obtained via the signal processing unit 108, and calculates the distance on the basis of the pattern distortion.

Subsequently, the ToF method is a method for measuring a distance to an object by detecting a flight time (time difference) of light emitted from the light emitting unit 102 until the light is reflected by the object and reaches the light receiving unit 107.

In a case where a so-called direct ToF (dToF) method is adopted as the ToF method, a single photon avalanche diode (SPAD) is used as the light receiving unit 107, and the light emitting unit 102 is pulse-driven. In this case, the distance measuring unit 109a calculates a time difference between light emission and light reception for light emitted from the light emitting unit 102 and received by the light receiving unit 107 on the basis of a signal input via the signal processing unit 108, and calculates a distance to each unit of the subject S on the basis of the time difference and the speed of light.

Note that, in a case where a so-called indirect ToF (iToF) method (phase difference method) is adopted as the ToF method, for example, a light receiving unit capable of receiving IR is used as the light receiving unit 107.

Note that the light emitting devices of the first to twelfth embodiments are used as the light source of the distance measuring device 101 in the thirteenth embodiment, but may be used in other modes. For example, the light emitting devices of these embodiments may be used as the light source of an optical device such as a printer, or may be used as a lighting device.

Furthermore, the substrate 1 of the first to twelfth embodiments may be a compound semiconductor substrate other than the GaAs substrate. For example, the substrate 1 of the first to twelfth embodiments may be a gallium nitride (GaN) substrate or indium phosphide (InP). The substrate 1 of the first to twelfth embodiments may be produced by various materials having an oscillation wavelength region of 200 to 2000 nm.

Furthermore, the light constriction structure of the first to twelfth embodiments may be formed in a form other than the step structure or the oxidation constriction structure. Furthermore, the current constriction structure of the first to twelfth embodiments may be formed in a form other than the high resistance structure or the oxidation constriction structure.

Furthermore, a shape of the OA portion and the mesa in plan view may be any shape. For example, the shape of the OA portion and the mesa in plan view may be a circular shape, an elliptical shape, a triangle shape, a quadrangular shape, other polygonal shape, or the like.

Although the embodiments of the present disclosure have been described above, these embodiments may be implemented with various modifications within a scope not departing from the gist of the present disclosure. For example, two or more embodiments may be implemented in combination.

Note that the present disclosure can also have the following configurations.

1

A light emitting device including:
an active layer having a first surface on a first substrate side and a second surface on a side opposite to the first substrate;
a first reflector provided on the first surface side of the active layer;
a second reflector provided on the second surface side of the active layer;
a first semiconductor layer provided on the first surface side of the active layer and having a first conductivity type;
a second semiconductor layer provided on the second surface side of the active layer and having a second conductivity type;
a first electrode electrically connected to the first semiconductor layer; and
a second electrode electrically connected to the second semiconductor layer, in which
the first electrode and the second electrode are separated from each other by a first insulating film provided between the first electrode and the second electrode, and
a surface of the first electrode on a side opposite to the first substrate, a surface of the second electrode on a side opposite to the first substrate, and a surface of the first insulating film on a side opposite to the first substrate are located in a same plane.
   2

The light emitting device according to (1), in which the second electrode is in contact with a side wall of the second reflector.

3

The light emitting device according to (1), in which the first electrode has a shape surrounding the second electrode in plan view.

4

The light emitting device according to (1), in which the first insulating film includes the second reflector that is an insulating film.

5

The light emitting device according to (1), in which
the first electrode is provided inside or on side surfaces of the active layer, the second reflector, and the second semiconductor layer, and
the second electrode is provided inside or on a side surface of the second reflector or on a surface of the second reflector on a side opposite to the substrate.
   6

The light emitting device according to (5), in which
the first electrode is provided inside or on side surfaces of the active layer, the second reflector, and the second semiconductor layer with a second insulating film interposed in between, and
the first insulating film includes the second insulating film.
   7

The light emitting device according to (5), in which
the second electrode is provided inside the second reflector that is a semiconductor layer, with a third insulating film interposed in between, and
the first insulating film includes the third insulating film.
   8

The light emitting device according to (1), in which a ratio of the surface of the first insulating film to the plane is larger than a ratio of the surface of the first electrode and the surface of the second electrode to the plane.

9

The light emitting device according to (1), in which a ratio of the surface of the first electrode to the plane is larger than a ratio of the surface of the second electrode and the surface of the first insulating film to the plane.

10

The light emitting device according to (1), further including: a current constriction region having a ring shape in plan view and provided in the active layer, the first reflector, the second reflector, the first semiconductor layer, or the second semiconductor layer.

11

The light emitting device according to (10), in which
the current constriction region includes:
a first current constriction region provided in the active layer and having a first inner diameter in plan view; and
a second current constriction region provided in the active layer and the second semiconductor layer and having a second inner diameter larger than the first inner diameter in plan view.
   12

The light emitting device according to (10), in which the current constriction region is in contact with the second reflector and the second electrode.

13

The light emitting device according to (10), in which the current constriction region is an oxide film.

14

The light emitting device according to (1), in which the first semiconductor layer is provided between the active layer and the first reflector or in the first reflector.

15

The light emitting device according to (1), in which the active layer, the first reflector, the second reflector, the first semiconductor layer, and the second semiconductor layer form a plurality of light emitting elements.

16

The light emitting device according to (15), in which the second electrode of each light emitting element is separated from the second electrode of another light emitting element.

17

The light emitting device according to (16), in which the second electrode of each light emitting element is separated from the second electrode of another light emitting element by the first insulating film.

18

The light emitting device according to (15), further including:
a light emitting element substrate including the first substrate, and including the active layer, the first reflector, the second reflector, the first semiconductor layer, and the second semiconductor layer that are provided on the first substrate; and
a wiring substrate bonded to the light emitting element substrate and including a second substrate and wiring provided on the second substrate for the plurality of light emitting elements.
   19

A method for manufacturing a light emitting device, the method including:
forming, on a first substrate, an active layer having a first surface on the first substrate side and a second surface on a side opposite to the first substrate, a first reflector provided on the first surface side of the active layer, a second reflector provided on the second surface side of the active layer, a first semiconductor layer provided on the first surface side of the active layer and having a first conductivity type, and a second semiconductor layer provided on the second surface side of the active layer and having a second conductivity type;
forming, on the first substrate, a first electrode electrically connected to the first semiconductor layer; and
forming, on the first substrate, a second electrode electrically connected to the second semiconductor layer, in which
the first electrode and the second electrode are formed to be separated from each other by a first insulating film provided between the first electrode and the second electrode, and
a surface of the first electrode on a side opposite to the first substrate, a surface of the second electrode on a side opposite to the first substrate, and a surface of the first insulating film on a side opposite to the first substrate are formed to be located in a same plane.
   20

The method for manufacturing the light emitting device according to (19), in which the surface of the first electrode, the surface of the second electrode, and the surface of the first insulating film are formed to be located in a same plane by being planarized by polishing.

### Reference Signs List

1 Substrate
2 First current injection layer
3 First DBR
3′ First DBR
4 Active layer
4a Constriction layer
5 Second current injection layer
6 Second DBR
6′ Second DBR
11 Implantation region
11a First implantation region
11b Second implantation region
12 Insulating film
13 First electrode
14 Second electrode
14a Lower layer
14b Upper layer
21 Electrode material
31 Insulating film
41 LD chip
42 LDD substrate
51 Wiring layer
52 Via plug
53 Wiring layer
54 Via plug
55 Wiring layer
56 Substrate
57 Insulating film
101 Distance measuring device
102 Light emitting unit
102a Light emitting element
103 Drive unit
104 Power supply circuit
105 Light-emitting side optical system
106 Light-receiving side optical system
107 Light receiving unit
108 Signal processing unit
109 Control unit
109a Distance measuring unit
110 Temperature detection unit

1. A light emitting device comprising:
an active layer having a first surface on a first substrate side and a second surface on a side opposite to the first substrate;
a first reflector provided on the first surface side of the active layer;
a second reflector provided on the second surface side of the active layer;
a first semiconductor layer provided on the first surface side of the active layer and having a first conductivity type;
a second semiconductor layer provided on the second surface side of the active layer and having a second conductivity type;
a first electrode electrically connected to the first semiconductor layer; and
a second electrode electrically connected to the second semiconductor layer, wherein
the first electrode and the second electrode are separated from each other by a first insulating film provided between the first electrode and the second electrode, and
a surface of the first electrode on a side opposite to the first substrate, a surface of the second electrode on a side opposite to the first substrate, and a surface of the first insulating film on a side opposite to the first substrate are located in a same plane.

2. The light emitting device according to claim 1, wherein the second electrode is in contact with a side wall of the second reflector.

3. The light emitting device according to claim 1, wherein the first electrode has a shape surrounding the second electrode in plan view.

4. The light emitting device according to claim 1, wherein the first insulating film includes the second reflector that is an insulating film.

5. The light emitting device according to claim 1, wherein
the first electrode is provided inside or on side surfaces of the active layer, the second reflector, and the second semiconductor layer, and
the second electrode is provided inside or on a side surface of the second reflector or on a surface of the second reflector on a side opposite to the substrate.

6. The light emitting device according to claim 5, wherein
the first electrode is provided inside or on side surfaces of the active layer, the second reflector, and the second semiconductor layer with a second insulating film interposed in between, and
the first insulating film includes the second insulating film.

7. The light emitting device according to claim 5, wherein
the second electrode is provided inside the second reflector that is a semiconductor layer, with a third insulating film interposed in between, and
the first insulating film includes the third insulating film.

8. The light emitting device according to claim 1, wherein a ratio of the surface of the first insulating film to the plane is larger than a ratio of the surface of the first electrode and the surface of the second electrode to the plane.

9. The light emitting device according to claim 1, wherein a ratio of the surface of the first electrode to the plane is larger than a ratio of the surface of the second electrode and the surface of the first insulating film to the plane.

10. The light emitting device according to claim 1, further comprising: a current constriction region having a ring shape in plan view and provided in the active layer, the first reflector, the second reflector, the first semiconductor layer, or the second semiconductor layer.

11. The light emitting device according to claim 10, wherein
the current constriction region includes:
a first current constriction region provided in the active layer and having a first inner diameter in plan view; and
a second current constriction region provided in the active layer and the second semiconductor layer and having a second inner diameter larger than the first inner diameter in plan view.

12. The light emitting device according to claim 10, wherein the current constriction region is in contact with the second reflector and the second electrode.

13. The light emitting device according to claim 10, wherein the current constriction region is an oxide film.

14. The light emitting device according to claim 1, wherein the first semiconductor layer is provided between the active layer and the first reflector or in the first reflector.

15. The light emitting device according to claim 1, wherein the active layer, the first reflector, the second reflector, the first semiconductor layer, and the second semiconductor layer form a plurality of light emitting elements.

16. The light emitting device according to claim 15, wherein the second electrode of each light emitting element is separated from the second electrode of another light emitting element.

17. The light emitting device according to claim 16, wherein the second electrode of each light emitting element is separated from the second electrode of another light emitting element by the first insulating film.

18. The light emitting device according to claim 15, further comprising:
a light emitting element substrate including the first substrate, and including the active layer, the first reflector, the second reflector, the first semiconductor layer, and the second semiconductor layer that are provided on the first substrate; and
a wiring substrate bonded to the light emitting element substrate and including a second substrate and wiring provided on the second substrate for the plurality of light emitting elements.

19. A method for manufacturing a light emitting device, the method comprising:
forming, on a first substrate, an active layer having a first surface on the first substrate side and a second surface on a side opposite to the first substrate, a first reflector provided on the first surface side of the active layer, a second reflector provided on the second surface side of the active layer, a first semiconductor layer provided on the first surface side of the active layer and having a first conductivity type, and a second semiconductor layer provided on the second surface side of the active layer and having a second conductivity type;
forming, on the first substrate, a first electrode electrically connected to the first semiconductor layer; and
forming, on the first substrate, a second electrode electrically connected to the second semiconductor layer, wherein
the first electrode and the second electrode are formed to be separated from each other by a first insulating film provided between the first electrode and the second electrode, and
a surface of the first electrode on a side opposite to the first substrate, a surface of the second electrode on a side opposite to the first substrate, and a surface of the first insulating film on a side opposite to the first substrate are formed to be located in a same plane.

20. The method for manufacturing the light emitting device according to claim 19, wherein the surface of the first electrode, the surface of the second electrode, and the surface of the first insulating film are formed to be located in a same plane by being planarized by polishing.
